(19) United States
(12) Patent Application Publication
(10) Pub. No.: US 2003/0162399 A1
(43) Pub. Date: Aug. 28, 2003

(54) Method, composition and apparatus for tunable selectivity during chemical mechanical polishing of metallic structures

(75) Inventor: Rajiv K. Singh, Gainesville, FL (US)

Correspondence Address: Gregory A. Nelson, Esq., Akerman, Senterfitt & Eidson, P.A., 222 Lakeview Avenue, 4th Floor, P.O. Box 3188, West Palm Beach, FL, 33402-3188, US

(73) Assignee: University of Florida, Gainesville, FL

(21) Appl. No.: 10/263,063

(22) Filed: Oct. 1, 2002

Related U.S. Application Data
(63) Continuation-in-part of application No. 10/082,010, filed on Feb. 22, 2002.
(63) Continuation-in-part of application No. 10/081,979, filed on Feb. 22, 2002.

(51) Int. Cl. H01L 21/302; H01L 21/461

(52) U.S. Cl. 438/692

(57) ABSTRACT

A slurry and method for chemical mechanical polishing (CMP) a structure including at least one metal based film and at least one underlying dielectric film includes at least one selective adsorption additive, such as a surfactant or a polymer. The metal film does not substantially adsorb the selective adsorption additive surfactant, while dielectric film substantially adsorbs the selective adsorption additive. A plurality of composite particles can be added, such as inorganic cores surrounded by the selective adsorption additive. In another embodiment, a slurry and method for polishing a metal film and an underlying dielectric film includes polishing during a first time interval using a first slurry composition and polishing during a second time interval with a second slurry composition, wherein a selectivity ratio for metal/dielectric polishing using the first slurry composition to the metal/dielectric selectivity using the second slurry composition is at least 1.3.

### CROSS-REFERENCE TO RELATED APPLICATIONS

This application is a Continuation-In-Part of patent application Ser. No. 10/082,010 filed Feb. 22, 2002 entitled SLURRY AND METHOD FOR CHEMICAL MECHANICAL POLISHING OF METAL STRUCTURES INCLUDING REFRACTORY METAL BASED BARRIER LAYERS and application Ser. No. 10/081,979 filed Feb. 22, 2002 entitled IMPROVED CHEMICAL-MECHANICAL POLISHING SLURRY FOR POLISHING OF COPPER OR SILVER FILMS.

### STATEMENT REGARDING FEDERALLY SPONSORED RESEARCH OR DEVELOPMENT

Not applicable

### FIELD OF THE INVENTION

This invention relates to slurries, methods, and apparatus for chemical-mechanical polishing of structures including metal and dielectric layers.

### BACKGROUND

Reductions in semiconductor device dimensions provide higher densities and improved performance for integrated circuits. In many integrated electronic devices, millions of discrete elements, such as transistors, resistors and capacitors, are interconnected. Due to an increase in device density provided by scaling of semiconductor processes to improve circuit performance, it is no longer generally possible to utilize a single metal interconnect level. Single level interconnects result in significant parasitic resistance which can adversely affect device performance, particularly the dynamic performance of the integrated circuit.

Copper has become an increasingly popular choice for interconnect metal and has begun replacing aluminum in certain applications. Copper is much more conductive than aluminum, allowing finer wires having lower resistive losses. Copper is also significantly less vulnerable to electromigration than aluminum and less likely to fracture under stress. Electromigration is the drift of metal atoms when a conductor carries high current densities, and can create reliability problems through generation of voids and other defects.

Although copper provides advantages over aluminum, it has at least one major disadvantage. Copper is poisonous to silicon since it readily diffuses into silicon and causes deep-level defects. Therefore, copper must be isolated from silicon, usually through the use of a suitable refractory metal based barrier layer.

Multilevel metallization structures have been developed which include an interconnect structure having several levels of metallization separated by thin insulating layers. Metal plugs are used to connect the different metal levels to one another. Presently, aluminum alloys (e.g. Al/Si/Cu) are still commonly used for the metal interconnect, while tungsten is generally used for plug structures as the material of choice for interconnecting two levels of metals. Aluminum and its alloys are generally dry etched, such as by reactive ion etching and plasma etching. However, dry etching of copper is not currently feasible. Accordingly, when copper and its alloys are used instead of conventional aluminum or aluminum alloys as an interconnection material, alternative techniques are employed to define the copper lines.

For example, a damascene process together with chemical-mechanical polishing (CMP) can be used to define copper lines. In a damascene process, trenches are etched in a dielectric material, such as silicon dioxide (SiO₂). A barrier material is then deposited, generally by sputtering. Copper is then deposited typically using electrodeposition techniques (e.g. electroplating) to fill the barrier lined trenches. The overburden regions of the copper film are then removed by CMP to define the copper lines.

As copper is considered to be a killer impurity in silicon, typically the first metal layer is not made of the copper/refractory layer combination. Instead tungsten is generally used as a material of choice for the formation of the first metal layer. The process for the formation of a tungsten interconnect is similar to copper. Typically, the dielectric layer, such as silicon dioxide, is patterned using lithographic techniques and a refractory layer (such as titanium nitride) is deposited onto the surface of the silicon dioxide layer. This tungsten film is deposited typically by a CVD process and used to make the tungsten structures, the tungsten overburden generally removed using a CMP process.

CMP combines both chemical action and mechanical forces and is commonly used to remove metal overlayers in damascene processes, remove excess oxide in shallow trench isolation steps and to reduce topography across a dielectric region. Components required for CMP include a chemically reactive liquid medium and a polishing surface to provide the mechanical control required to achieve planarity.

Either the liquid or the polishing surface may contain nano-size inorganic particles to enhance the reactive and mechanical activity of the process. Typically, a chemically modified thin layer on the wafer surface is formed, such as a metal oxide, and then abrasives are used to remove the chemically modified layer from the surface. Once the surface layer is removed, a thin passive film is reformed rapidly on the surface and controls the removal process. CMP is the only technique currently known for producing die level flatness required for sub 0.5 μm devices and is considered a requirement for the production of sub 0.2 μm device structures and state-of-the-art metal interconnect schemes.

Metals can also be used to form the gate electrode of certain devices. In this case, the metal gate can provide the electrical pathway for switching the device. In the case of a MOS transistor, the gate dielectric is typically silicon dioxide while the typical gate electrodes presently used are generally formed from heavily doped polysilicon. Alternative gate dielectrics having improved properties may soon replace SiO₂. For example, novel high dielectric constant materials such as yttria, zirconia, hafnia, lanthanum oxide, and certain silicates are expected to find increasing use for future high performance applications.

To use novel high dielectric constant gate dielectrics more efficiently, gate electrode materials such as Ta, Cu and Pt may also become used. Other possible metallic materials may include Os, Ru, TiN, TaSiN, IrO₂, RuO₂ and other conducting oxides such as tin oxide (SnO₂), indium tin oxide, and related mixtures and alloys as well as, their nitrides and carbides. Copper may be deposited on top of these materials. Other emerging applications such as ferroelectric random access memory devices (FeRAM), tunneling magnetoresistance (TMR) or giant magnetoresistance (GMR) devices, where copper is deposited on a metal or a dielectric structure. In a FeRAM, copper may be used as the interconnecting metal or as sandwich metal layer on a gate electrode system. In a TMR or a GMR device, copper can be used as a back terminal, front end terminal or an electrode on a multilayer magnetic/non-magnetic structure. To create these specific structures it is also essential to remove copper selectively from the surface, but not to remove the underlying dielectric or metallic material.

The dielectric used in multiple level interconnect structures is typically silicon dioxide or doped silicon dioxide. With the rapid progression in device speeds to 2 GHz or more, circuit performance has become increasingly limited by the interconnect system. Thus, it has become increasingly important to use inter-metal dielectric materials which have a dielectric constant (K) below that of silicon dioxide, which has a dielectric constant of approximately 4. Dielectrics which have a dielectric constant less than 3.5 are typically referred to as “low K” materials. Examples of low K materials which may find increasing use as device speeds increase include doped silicon oxide, such as Black Diamond™ produced by the Applied Materials Corporation, Santa Clara, Calif. Introducing low K dielectric materials as inter-metal dielectric can produce a major improvement in device performance by lowering the line-to-line capacitance which increases device speed by reducing interconnect RC delay. These materials also can reduce cross-talk noise in the interconnect and can alleviate power dissipation issues. Dielectrics such as alumina and related materials (such as doped alumina) can also be used in magnetic applications.

FIG. 1 shows a schematic view of the steps and the resulting structures in a copper damascene CMP process. A low dielectric constant material disposed on a silicon wafer is patterned by suitable etching to form a plurality of trenches 110 as shown in FIG. 1(a). A diffusion barrier layer 120, such as Ti, Ta, WN, TaSiN or TaN, is then applied to cover the wafer surface, including the trenches 110 as shown in FIG. 1(b). A copper or copper alloy layer 130 is then deposited, by a method such as electroplating. (FIG. 1(c)). The copper or copper alloy layer is isolated from the remainder of the circuit by the barrier layer 120. Copper (or metal in general) disposed over dielectric plateaus is commonly referred to as overburden metal 131.

A CMP process can then be used to define the copper layer through an essentially planar removal process. The CMP process proceeds to remove the copper layer sufficient to remove the overburden portion 131 to expose the barrier layer in the overburden regions to produce the structure 140 shown in FIG. 1(d). A second CMP step, generally using a different slurry as compared to the copper CMP process, is then used to polish the barrier layer and produce the completed structure 150 which is shown in FIG. 1(e). This process can be repeated to produce multiple copper or other conductor levels to form a plurality of interconnect or other levels.

Whether an interconnect or a gate electrode is formed using CMP, it is important to stop the CMP process soon after the metal layer is fully removed to minimize removal of underlying layers. Since the metal thickness and polishing rates can be non-uniform across the wafer area, it is also helpful for the CMP process to provide a low polishing rate of the underlying layers below the metal, relative to the metal removal rate.

A diagram of a conventional CMP polisher 200 is shown in FIG. 2. The CMP polisher includes a polishing pad 210 disposed on a platen 220 which rotates. A wafer 230 is pressed into direct contact with the polishing pad 210 by a force exerting structure 250. A slurry solution is provided by a slurry feed 240 to wet the polishing pad 210 which chemically and physically interacts with the surface of the wafer 230.

Conventional slurries used for the CMP include a solid abrasive and an oxidizing substance. Typically, CMP polishing slurries contain a plurality of alumina or silica particles suspended in an oxidizing aqueous medium. In FIG. 2, the polishing pad 210 is attached to the top of the rotating platen 220, while the wafer 230 is brought in contact with the pad 210 from the top. The wafer 230 can either be rotated or kept stationary. The wafer 230 can be moved in a circular, elliptical or in a linear manner with respect to the polishing pad 210. The pressure on the wafer 230 is generally varied from 0.1 psi to 10 psi, and the rotation speed of the platen 220 is generally varied from 5 rpm to 200 rpm.

The polymeric polishing pad 210 transports the slurry beneath the wafer and participates in the wafer-particle-pad interaction responsible for removal of the material. Typical pads which are commonly used include IC1000 CMP pads manufactured by Rodel Corporation, located in Newark, Del.

The diameter of the platen wheels 220 can vary from 10 inches to 45 inches, while the size of the wafer can vary from 1 inches to 12 inches in diameter. To maintain a fixed linear velocity, either the angular velocity can be increased or the radius of the wafer from the center can be increased. It is generally important to generate a linear movement of the pad across the wafer.

Slurries designed to polish metallic layers contain abrasives such as alumina, titania and silica, oxidizing agents such as hydrogen peroxide, potassium ferricyanide, ferric nitrate, ferric chloride and other optional additives. Aggressive polishing methodologies are generally used to remove the metal layers such as tantalum, Pt, W and Cu. As a result, the generally soft surface layers underlying the tantalum layer, such as SiO₂ or a low K material, can be damaged. For example, scratches can result which can degrade circuit performance and yield and may also degrade reliability of the integrated circuits. Moreover, the use of conventional metal based slurry chemistries are known to result in several other problems, such as surface defects, dishing and erosion problems, and film peeling.

Metal film polishing can result in dishing and erosion effects. Dishing results in the surface of the central part the metal interconnection being inlaid in a groove formed on the insulating film due to excessively polishing of the central part compared to the periphery. Erosion occurs when the insulating surface around the interconnection is polished. In erosion, both the metal and the insulating areas are depressed, whereas in dishing, the metal lines are depressed compared to metal based film or the underlying insulating film. These defects generally result because the polishing rates of the metal and dielectric films are quite different for the same slurry. When the metal and the dielectric films are juxtaposed to each other, the metal lines can be depressed, or vice versa. For very fine metal and dielectric structures both the metal and dielectric area can be eroded. This phenomena is generally observed in substantially all CMP metal polishing.

Metal based film polishing can also result in the loss of the dielectric materials during the polishing process. The underlying dielectric materials are typically doped or undoped silicon dioxide or other low dielectric constant material such as carbon doped silica or certain polymeric materials. After polishing the metal based film, the underlying dielectric layer becomes exposed. The slurry abrasives, such as silica or alumina, are typically hard and abrasive. These abrasives can also cause significant dielectric erosion and surface defects upon the underlying substrate.

The dielectric loss typically increases as the concentration of particles increase in the slurry, and increases for increasingly alkaline pH (pH>7 to 12). High dielectric erosion can cause surface non-planarity and loss of global planarization. To reduce the dielectric erosion during metal polishing, it has been suggested to use slurries which do not contain particles or only a low concentration of particles, such as 0.5 wt. % alumina particles. Reduced particle concentrations can be expected to reduce the dielectric loss. However, reduced abrasive particle concentrations are also expected to substantially reduce the metal polishing rate.

Metal based film polishing can also result in the introduction of surface defectivity on the final surface. The final surface generally consists of thin copper lines and contact hole plugs within a dielectric matrix. The dielectric is typically doped or undoped silicon dioxide, or possibly a new low-K dielectric material. The surface defectivity is characterized by scratches on the surface of metal and insulator, surface roughness due to etching effects, and the presence of particles which can become attached to the surface. As most metal based film slurries contain hard abrasives such as alumina or silica, these particles tend to scratch the surface of the dielectric and copper. To reduce the surface defectivity, the amount of hard abrasives can be reduced, but this problem still persists.

Metal based film polishing can also result in film peeling of underlying layers. The underlying dielectric film is typically soft and may have poor adhesion to its underlying layer which can produce a tendency to peel. With the advent of new low dielectric constant thin films generally being softer than silicon dioxide, film peeling is expected to worsen. Standard slurries, which use hard abrasives such as silica and alumina, can damage, peel and delaminate the dielectric layer quite easily. Besides peeling and delamination of the surface, the hard abrasives can cause scratches, which can also reduce the yield and reliability of devices. To reduce the possibility of peeling, slurries can use softer particles, such as polymers. However, polymer particles are not expected to be effective for removing metal based films, such as tantalum. Thus, the soft particle approach is not practical for polishing metal based films.

Metal based film slurries can also cause destabilization of the slurry abrasives leading to agglomeration. Agglomeration can provide several unwanted effects in the CMP process including the formation of a large number of surface defects, wide variation in the CMP polishing rates and lack of process repeatability.

It is critical to stop the CMP process soon after all the overburden metal is removed from the surface. Sophisticated end-point detection systems are generally installed in the CMP polisher to detect changes in the properties of the wafer surface. Typically, the overburden metal does not clear from all the areas of the surface at the same time. If the underlying dielectric has finite polishing rate, then varied removal rates occur at different regions on the surface, thus leading to polish topography and surface non-uniformity.

To decrease the non-uniformity during polishing, slurry chemistries which selectively polish the metal compared to the underlying dielectric need to be developed. The selectivity of the metal polishing compared to the dielectric (denoted as selectivity) should be high so that the polishing process essentially stops once the overburden metal layer is removed. Typical selectivities obtained by particle based slurries are in the range of 50 or less. Although this level of selectivity maybe adequate for some polishing applications, higher selectivities are more desirable. However, because slurries are composed of particles which have relatively high polishing rate for the dielectric, higher selectivities have not been achieved. The availability of high selectivity slurries for metal polishing is expected to further improve the determination of the end point and prevent dielectric loss.

Although higher metal to dielectric selectivities are highly desirable, it may lead to an increase in surface topography near the end of the polishing process. This happens because the embedded metal layers have a much higher removal rate compared to the dielectric. This can lead to dishing at the surface. Thus, methods to improve the planarity of high selectivity slurries need to be developed.

### SUMMARY OF THE INVENTION

A slurry is provided for chemical mechanical polishing (CMP) of a structure including at least one metal based film and at least one underlying dielectric film. The term “metal-based film” refers to highly electrically conductive materials, such as aluminum, copper, Ni, Fe, noble metals, refractory metals, related electrically conducting oxides and nitrides of these materials, and mixtures thereof The term conducting materials generally provide an electrical resistivity of less than about 100 micro-ohm-cm. Conducting materials may include noble metals and/or refractory materials. Refractory metals can include tungsten, tantalum, iridium, hafnium, titanium, their oxides, ruthenium nitrides and carbides, silicides and their mixtures. Noble metals can include metals such as platinum, gold, silver and their alloys, mixtures and compounds thereof. As used herein, structure generally refers to one or more metallic layers embedded in a dielectric matrix. The term “dielectric” refers to electrically non-conducting materials, such as amorphous silicon dioxide (doped and doped), silica, low K dielectrics, high K dielectrics, alumina, and silicon nitride.

The slurry can include a continuously applied (“continuous slurry”) which is either an abrasive based or abrasive-free slurry and one or more slurries which are applied at one or more intervals during the polishing process (“interval slurries”). The continuous slurry provides high polishing selectivity for either top metal to a refractory layer and/or for metal to dielectric layer polishing. When the interval slurry is mixed with the continuous slurry, the resulting mixed slurry provides reduced selectivity. The term “polishing selectivity” as used herein refers to the ratio of the polishing rates of a top layer typically being a highly conducting metal layer or a refractory metal layer, and an underlying layer which may either be a refractory metal layer or a dielectric layer. “High selectivity” refers to selectivity values greater than 40, and preferably greater than 100. Tunable selectivity means the ability to change the polishing selectivity during the polishing process.

The continuous slurry may include at least one selective adsorption additive, wherein the selective adsorption additive is substantially adsorbed by the dielectric film, but is not substantially adsorbed by the metal based film. As used herein, the term “substantial adsorption” relative to a given layer is defined herein as a CMP polishing rate (for a given slurry and CMP polishing conditions) without the selective adsorption additive being at least three (3.0) times the CMP polishing rate obtained when the slurry includes the selective adsorption additive. On the other hand, non-substantial adsorption relative to a given film is defined herein as a CMP polishing rate (for a given slurry and CMP polishing conditions) without the selective adsorption additive being less than three (3.0) times the polishing rate of the layer obtained when the slurry includes the selective adsorption additive.

In another embodiment, the continuous abrasive based slurry based on at least one selected adsorption additive shows substantial adsorption only below a predetermined pressure range, and non-substantial adsorption above this pressure range. The certain pressure range can be between 0 to 5 psi, 1 to 10 psi or 2 to 18 psi.

The slurry preferably includes a plurality of particles. The particles can comprise composite particles, the composite particles including an abrasive core surrounded by a shell including the selective adsorption additive. Abrasive cores can be multiphase particles, the multiphase particles comprising a first material coated with at least one other material. An abrasive based slurry including the selective dielectric adsorption additive can include at least one oxidizer such as peroxides, iodates, bromates, chlorates, permanganates, ferricyanides, nitrous acid, hypochlorites, hypobromidies, hypoiodides, perchlorates and perbromates.

The selective adsorption additive can comprise at least one surfactant selected from cationic, anionic, non-ionic and zwitterionic surfactants. A CMP process using this slurry can provides a selectivity of at least 30 for the metal based film as compared to a dielectric film. The dielectric film can be silicon dioxide, silicon nitride, silicon oxynitride, alumina or a low K dielectric. As used herein, “low K dielectrics” refer to materials having dielectric constants less than about 3.5, such as fluorine, carbon, and/or nitrogen doped silica, nanoporous materials, and polymeric materials such as SiLK (manufactured by Dow Chemicals).

The structure being polished can be a refractory metal based barrier film disposed between the metal based film and the dielectric film, the metal film comprising copper or silver, wherein a CMP process using the slurry provides a selectivity of at least approximately 50 for the metal based film as compared to the refractory metal based film or the dielectric film.

The slurry can include one or more soft layer formation additives which can be used to form a surface layer on the metal surface that is softer than the metal surface. As used herein, the term “soft layer” on a metal surface refers to a surface film which provides a Mohs hardness of less than 3, and preferably less than 2. Examples of soft layers include metal halide layers such as chlorides, bromides, iodides, hydroxide, sulfides, nitrides or their mixtures. Other examples of soft layers includes complexes of halides with surfactants, salts, complexing agents and corrosion inhibitors. A preferred soft layer includes copper-azoles-halide complexes. As used herein, non-oxide surface layers refer to surface layers whose primary phases include halide layers such as chlorides, iodide, bromides, sulfides and hydroxides and mixtures of these materials with oxide, nitride and complexation compounds. Preferably the soft layer is a non oxide layer. The soft layer formation additive preferably does not interact strongly with the underlying refractory metal (if present) or the dielectric layer, thus resulting in low removal rate of the underlying layer(s) and high selectivity for the polishing process.

A slurry for chemical mechanical polishing (CMP) a structure which includes at least one metal based film embedded in a dielectric matrix or on top of a dielectric film, wherein the slurry comprises at least one additive which forms a soft layer on a surface of said metal based film. The metal based film can comprise copper, tungsten, silver, tantalum, and alloys or compounds thereof.

This slurry can include particles, or be operated without any added particles. Particles can be abrasive or soft particles. The term “abrasive-free” refers to the absence of particles in the slurry, or if particles are present, particles being soft or having soft surfaces, which is defined herein as a particle which provides a surface hardness less than 3.0 on the Mohs scale. Examples of soft particles include, talc, polymers, polystyrene, PTFE (teflon), titania, nanoporous silica with porosity greater than about 5%, or abrasive particles coated with a material having hardness of less than 3.0 on the Mohs scale. Silicon dioxide particles having an average size less than 150 nm in aqueous solution form a thin hydrated soft layer which significantly reduces its overall hardness and as a result behave as soft particles. The slurry can also include a plurality of abrasive particles. As used herein, the term “abrasive” refers to particles which have hardness greater or equal to 3.0 on the Mohs scale. Examples of abrasive particles in the slurry include silica, alumina, zirconia, yttria, silicon nitride, carbon, their mixtures, and their related compounds.

The soft layer can comprise at least one halide. The halide can be selected from the group consisting of iodides, bromides, chlorides and related compounds, and mixtures thereof. A CMP process using the slurry can provide a selectivity of at least 50 for the metal based film relative to the dielectric matrix or an underlying refractory metal based film. The dielectric matrix or dielectric film can comprise silicon dioxide, silicon nitride, silicon oxynitride, alumina or a low K dielectric.

A slurry for chemical mechanical polishing (CMP) a structure which includes at least one metal based film embedded in a dielectric matrix or on top of a dielectric film comprises at least one additive which forms a non-oxide layer on a surface of the metal based film. The additive can comprise a halide, such as an iodine containing material. The metal based film can comprises copper, tungsten, silver, tantalum, and alloys and compounds thereof. Non oxide surface layers refer to layers whose primary phases include halide layers such as chlorides, iodide, bromides, sulfides, hydroxides, or any other non-oxide layers. Primary phase refers to the composition comprising greater than 50% by weight in the film layer. This slurry can include either no particles or soft particles. Alternatively, the slurry can include abrasive particles, the abrasive particles having sizes less than 200 nm. The abrasive particles can comprise silicon dioxide, alumina or silicon nitride. A CMP process using the slurry can provide a selectivity of at least 50 for the metal based film relative to the dielectric matrix. The metal based film can comprises at least one refractory metal. The dielectric matrix or dielectric film can comprise silicon dioxide, silicon nitride, silicon oxynitride, alumina or a low K dielectric.

A slurry for chemical mechanical polishing a structure including at least one metal layer embedded in a dielectric matrix comprises at least one soft film forming material and a plurality of particles. The slurry can include at least one surfactant, the surfactant selected from anionic, non-ionic, cationic and zwitterionic surfactants. The soft film forming material can comprise a halide which reacts in the slurry to form halide ions or free halides in the slurry. The slurry can include at least one salt, such as chlorides, bromides, iodides, nitrates, pthalates and soluble potassium, sodium and ammonium based salts. The slurry can include at least one corrosion inhibitor and/or at least one complexing agent.

In another embodiment, the slurry can include at least two additives, such as surfactants, to provide pressure dependent selective adsorption. Below a certain pressure range, substantial adsorption takes place, while above a predetermined pressure, non substantial adsorption takes place.

A slurry for chemical mechanical polishing (CMP) a structure including a metal based film and an underlying dielectric film comprises a first slurry composition which provides a first selectivity for removal of the metal based film relative to the dielectric film, the first slurry for use during at least a first time interval, and a second slurry composition providing a second selectivity for removal of the metal film relative to the dielectric film for use beginning during at least a second time interval. The second time interval is after the first time interval, wherein a selectivity ratio of the first selectivity to the second selectivity is at least 1.3. The first slurry composition can comprise a plurality of abrasive particles and can provide a selectivity of at least 50. The metal film can comprise noble metals, refractory metals, Ni, Al, and Fe, and mixtures thereof. The dielectric film can be silicon dioxide, low K dielectrics or alumina.

A slurry for chemical mechanical polishing (CMP) a structure including a metal based film, an underlying dielectric film, and a refractory metal based barrier film disposed between the metal film the dielectric film comprises a first slurry composition providing a first selectivity for removal of the metal based film relative to the refractory metal based barrier film, the first slurry for use during at least a first time interval, and a second slurry composition providing a second selectivity for removal of the metal based film relative to the refractory metal based barrier film for use beginning during at least a second time interval. The second time interval is after the first time interval, wherein a selectivity ratio of said first selectivity to said second selectivity is at least 1.3.

The second slurry composition is generally formed by adding an additional slurry component (the interval slurry) to the first slurry (the continuous slurry). In one embodiment, the addition of the additional slurry component can affect the adsorption of the selective adsorption additive on the dielectric. This results in an enhanced removal rate of the underlying dielectric and reduced metal to dielectric selectivity which enhances the planarity of the metal/dielectric layer. In another embodiment, the interval slurry can also reduce the concentration of additives which form a soft layer on the surface of the metal in the overall mixed slurry leading to reduced selectivity of the polishing process. The interval slurry can also reduce the concentration of particles in the slurry which can also result in reduced selectivity.

The first slurry composition can include either a plurality of abrasive particles, no particles, or particles providing a surface hardness of no more than 3.0 on the Mohs scale (soft particles), or silicon dioxide particles having an average size less than 150 nm.

The first slurry can provide a first selectivity of at least 50, or at least 500. The structure to be polished can include a refractory metal based barrier film disposed between the metal film and the dielectric film, wherein a selectivity of the metal film relative to the refractory based metal film provided by the first slurry can be at least 50. The metal film can comprises noble metals, refractory metals Ni, Fe, and mixtures thereof. The dielectric film can be silicon dioxide, silica, a low K, dielectric or alumina.

A method for chemical mechanical polishing (CMP) a structure including a metal based film and an underlying dielectric film includes the steps of polishing during at least a first time interval using a first slurry composition, the first slurry providing a first selectivity for removal of the metal film relative to the dielectric film, and polishing during a second time interval, the second time interval after the first time interval, using a second slurry composition providing a second selectivity for removal of the metal film relative to the dielectric film, wherein a selectivity ratio of said the selectivity to the second selectivity is at least 1.3.

A method for chemical mechanical polishing (CMP) a structure including a metal based film and an underlying refractory metal based film includes the steps of polishing during at least a first time interval using a first slurry composition, the first slurry providing a first selectivity for removal of the metal film relative to the refractory metal based film, and polishing during a second time interval, the second time interval after said first time interval, using a second slurry composition providing a second selectivity for removal of the metal film relative to the refractory metal based film, wherein a selectivity ratio of the first selectivity to the second selectivity is at least 1.3.

An apparatus for chemical mechanical polishing (CMP) of structures including at least one metal film and at least one dielectric film comprises structure for applying a first slurry composition during a first time interval, the first slurry providing a first selectivity for removal of the metal film relative to the dielectric film, and structure for applying a second slurry composition during a second time interval, the second time interval after the first time interval, the apparatus providing a second selectivity removal of the metal film relative to the dielectric film, wherein a selectivity ratio of the first selectivity to the second selectivity is at least 1.3. The first slurry composition can include a plurality of abrasive particles, the first selectivity ratio being at least 3.

The first slurry can include either no particles, particles providing a surface hardness of no more than 3.0 on the Mohs scale, or silicon dioxide particles having an average size less than 150 nm. The second slurry composition can include the first slurry composition and at least one additional slurry additive. The apparatus can further comprise structure for mixing the additional slurry additive with the first slurry composition.

An apparatus for chemical mechanical polishing (CMP) of structures including at least one metal film and at least one refractory metal film comprises structure for applying a first slurry composition during a first time interval, the first slurry providing a first selectivity for removal of said metal film relative to the refractory metal film, and structure for applying a second slurry composition during a second time interval, said second time interval after the first time interval, the apparatus providing a second selectivity removal of the metal film relative to the refractory metal film, wherein a selectivity ratio of the first selectivity to the second selectivity is at least 1.3. When the first slurry composition can comprises a plurality of abrasive particles, the selectivity ratio can be at least 3. The second slurry composition can include the first slurry composition and at least one additional slurry additive. The first slurry composition can include either no particles, particles providing a surface hardness of no more than 3.0 on the Mohs scale or silicon dioxide particles having an average size less than 150 nm. The apparatus can include structure for mixing the additional slurry additive with the first slurry composition.

### BRIEF DESCRIPTION OF THE DRAWINGS

A fuller understanding of the present invention and the features and benefits thereof will be accomplished upon review of the following detailed description together with the accompanying drawings, in which:

FIGS. 1(a)-(e) shows a schematic of steps and the resulting structures during formation of copper based interconnects using a damascene process.

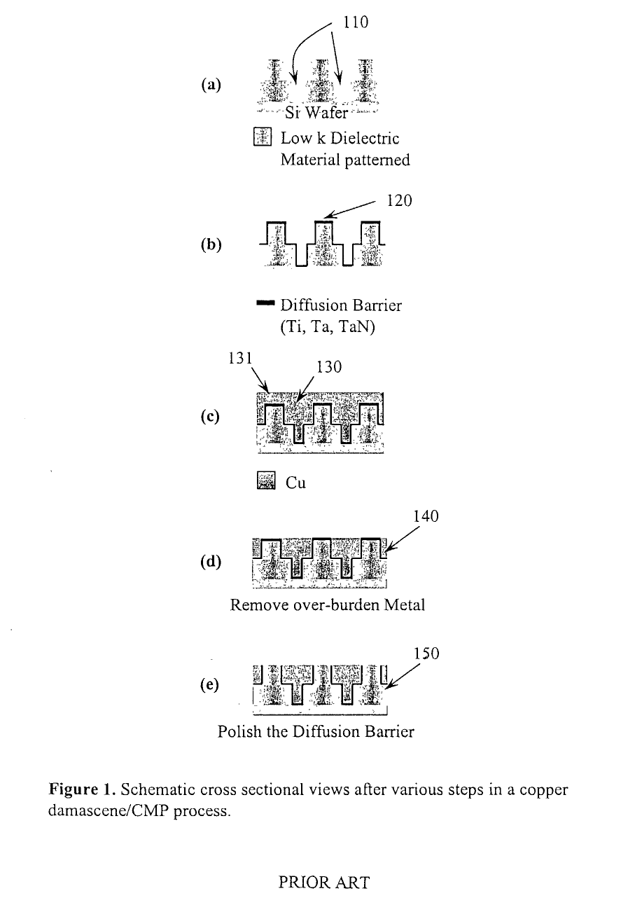

FIG. 2 is a perspective view of a conventional CMP polisher.

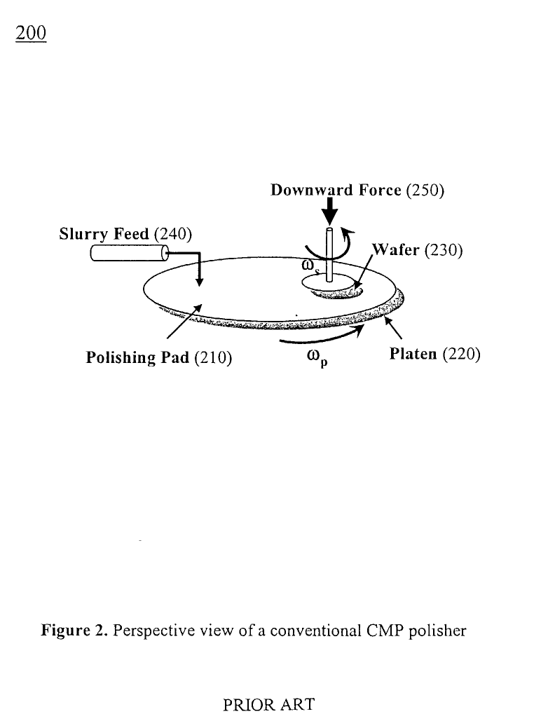

FIG. 3 is a schematic diagram showing use of an abrasive based continuous slurry to achieve high selectivity polishing.

FIGS. 4(a)-(d) are schematics of exemplary core particles for continuous abrasive based slurries.

FIGS. 5(a)-(c) are TEM photographs of coated particles which can be used in an abrasive based slurry.

FIGS. 6(a)-(c) are TEM photographs of nanoporous core particles.

FIGS. 7(a)-(c) illustrate some possible shell configurations for composite particles having various surfactant layer structures disposed on core particles.

FIG. 8 is a diagram showing time variation in the selectivity of a polishing process through the addition of an interval slurry for a period of time during a CMP process.

FIG. 9 illustrates a CMP apparatus adapted for dispensing a two component slurry for metal polishing.

### DETAILED DESCRIPTION OF THE PREFERRED EMBODIMENTS

The invention relates to slurries, methods and apparatus for polishing structures including metals and dielectrics, such as a metal layers embedded in a dielectric matrix. Two or more layers of metal, such as a top electrically conducting layer and bottom (e.g. refractory metal based) barrier layer, can be disposed on a patterned dielectric substrate. In certain structures, these layer stacks can be repeated to form multi-level metallization structures.

Slurries can include a continuous abrasive based or abrasive-free slurry, and one or more interval slurries. The continuous slurry is generally applied throughout the polishing process, while the interval slurry which comprises at least one additional slurry component, can be mixed with the continuous slurry, generally near the end of the polishing process. As used herein, the term “additional slurry component” includes increasing the concentration of any one or more components of the continuous slurry, or the addition of one or more slurry components which are not provided by the continuous slurry.

Mixed slurries including a continuous slurry and an interval slurry can achieve high and/or tunable selectivity between a metal layer and the underlying dielectric layer, and/or highly electrically conducting metal layer and underlying refractory metal based layer. The tunable selectivity aspect can be provided during the polishing process. The continuous slurry can provide high selectivity polishing while the mixed slurry comprising the continuous and interval slurry can provide tunable polishing selectivity at one or more specific time intervals during the polishing process. In one embodiment, the continuous slurry contains abrasive particles, while in another embodiment the continuous slurry is abrasive-free. The abrasive based continuous slurry may contain at least one adsorption additive which adsorbs selectively onto the dielectric layer, and/or includes at least one surface film formation additive which forms a soft layer and/or non-oxide layer on the surface of the electrically conducting metal or refractory metal layer. In a preferred embodiment, the selective adsorption additive exhibits substantial adsorption onto the dielectric below a predetermined pressure. The predetermined pressure can be in the range from 0 to 5 psi, 0 to 10 psi, or 0 to 18 psi. The abrasive-free slurry typically includes at least one film formation additive which forms a soft layer and/or non-oxide layer on the surface of the electrically conducting metal and/or refractory layer.

The term selectivity refers to the ratio of the polishing rate of the top layer, which is typically an electrically conducting metal layer or a refractory metal layer, and the underlying layer. The underlying layer may either be refractory metal layer or a dielectric layer. High selectivity refers to selectivity values greater than 40, and preferably greater than 100. The adsorption additive is typically a surfactant or a polymer. A soft film layer on the metal refers to surface layers which have a hardness less than 3.0, and preferably less than 2.5 on the Mohs scale. Examples of soft layers include metal halides such as chlorides, bromides, iodides, hydroxides, sulfides, nitride or their mixtures with themselves or with oxide materials. Other examples of soft layers includes complexes of halides with surfactants, salts, complexing agents and corrosion inhibitors. A preferred soft layer includes copper-azoles-halide complexes. Other examples of soft layers include complexes of halides with surfactants, salts, complexing agents and corrosion inhibitors. A preferred soft layer includes copper-azoles-halide complexes. Non-oxide surface layers refer to surface layers whose primary phases include halide layers such as chlorides, iodide, bromides, sulfides, hydroxides.

Application of the invention to these structures include metal polishing in semiconductor manufacturing such as for interconnects, gate structures in CMOS, FeRAM, BiCMOS, GMR, MRAM, devices in silicon, silicon-germanium, compound semiconductors based substrates. Other devices such as ferroelectrics and MEMS can also be formed using the invention.

A wide range of low-K dielectric materials, most having dielectric constants less than 3, comprising both inorganic and organic dielectric films, are currently available. These films are generally deposited using either spin-on or CVD processes.

Example of such inorganic dielectric materials include doped oxide, such as F-doped as FSG (fluorine silicate glass), H doped as HSQ, C and H doped as MSQ, HOSP, Black Diamond™, Coral™ manufactured by Novellus, and porous silica, such as aerogels, xerogels and nanoglass. For example, TEOS (tetraethylorthosilicate) FSG (flourinated silicate glass) is a silicon dioxide based material provided by Applied Materials that has been modified by the introduction of fluorine to lower the capacitance (K-value) of the dielectric film. Organic polymers can include amorphous fluorocarbon polymers, fluorinated polyimide, PTFE poly(arylene ether), benzocyclobutene, Silk™ and FLARE™.

The abrasive based continuous slurry can contain abrasive particles and at least one optional selective adsorption additive. The selective adsorption additive can be used to form a plurality of composite particles, consisting of an abrasive core and a soft shell comprising the selective adsorption additive. The soft shell may be non-substantially or substantially adsorbed on the surface of the particles. The selective adsorption additive is generally substantially adsorbed on the dielectric film and/or the particle, while weakly adsorbed on the metal layer.

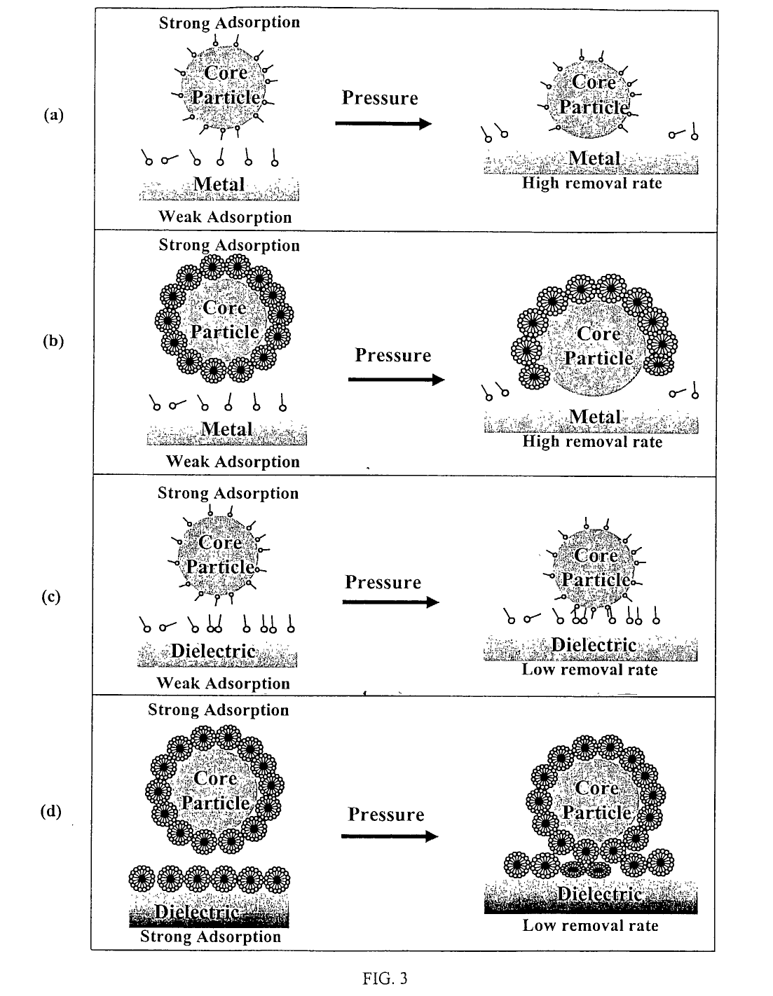

A schematic diagram showing use of a slurry including a substantial adsorption additive to achieve high metal to dielectric polishing selectivity is shown in FIG. 3. Due to strong adsorption on the dielectric film and/or the slurry particles, the polishing rate of the dielectric is substantially reduced. In contrast, non-substantial adsorption of the selective adsorption additive on the metal films occurs resulting in high removal rates of the metal film. Although formation of a soft-additive shell is not essential to achieve high selectivity, it is preferred.

In another embodiment, the selective adsorption additive shows substantial adsorption below a certain predetermined range, and non-substantial adsorption above this pressure range. In the preferred embodiment, the pressure range can be 0 to 5 psi, 0 to 10 psi, or between 1 and 18 psi.

The concentration of core particles in the continuous abrasive based slurry is generally from 0.1% to 40 wt. %. A preferred concentration range for composite particles is between 0.5 to 20 wt. %. Inorganic composite particles cores of the particles can be selected from at least four different types of particles. The cores can be inorganic single-phase particles, coated particles, mixed core particles and non-porous particles, or mixtures thereof.

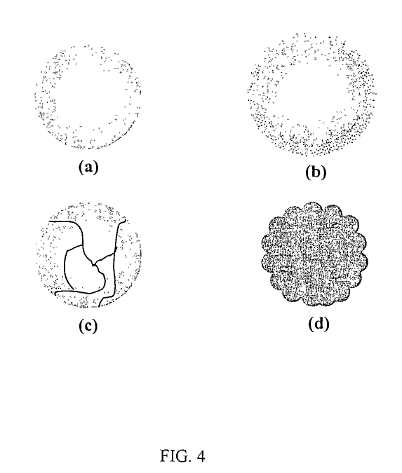

A pictorial representation of cores made up of the four different material types, being inorganic single-phase particles, coated particles, mixed composite particles and nano-porous particles are shown in FIGS. 4(a), (b), (c) and (d), respectively. The particles shown in FIGS. 4(b) and (d) are multiphase core particles, the multiphase core particles including two different materials. All the particle types shown can be made from known techniques, such as liquid based processes, gas based processes and dry/wet milling based processes.

The primary size of the core particles can vary from 5 nm to 50 microns. The preferred size is between 30 nm to 300 nm. The primary particle size refers to the minimum un-aggregated size of the particles. The cores of the composite particles can be selected to achieve desired mechanical, surface chemical and selective adsorption additive (surfactant or polymer) adsorption characteristics, respectively. For example, if a particular hardness and surface characteristic is desired, the inorganic core can be composed of a hard core, such as alumina, silicon nitride, and coated with a thin layer, such as silicon dioxide, low K dielectric or a non-soluble polymer. In a preferred embodiment, the surface of the core particles is chemically similar to the underlying dielectric surface. Thus, particles with specific desired mechanical and additive adsorption properties can be obtained. The mechanical properties of the composite particles are primarily controlled by the properties of the bulk material comprising the core, but the surfactant/polymer adsorption properties are controlled by the coated layer on the core particle.

It may also be possible to change the additive (surfactant or polymer) adsorption site density at surfaces including the surface of the core particles. This can be done by forming a core particle from two or more distinct phases, having a nanoporous particle structure, or putting a discontinuous coating on the surface. If a hydrophobic surface is desired, a metal or graphite particle or a non-soluble polymeric coating on the core particle can be used.

Single-phase core particles can be selected from materials, such as silica, zirconia, yttria, alumina, titania, silicon nitride, silicon carbide or its mixtures. Preferred examples of single phase core particles include compositions similar to the underlying dielectric material present in the structure to be polished, such as silicon dioxide, doped silicon dioxide, carbon doped silicon dioxide. A preferred single-phase core particle is silica. Multiphase core particles can be particles with an internal composition of either silica, zirconia, alumina, titania, silicon nitride, silicon carbide, ceria and manganese oxide or its mixtures having at least one optional solid coating of a thin layer of a metal, semiconductor or an oxide of these materials. Metal particles can include aluminum, titanium, copper or their alloys, while semiconducting particles can include silicon. These materials can include a surface thin oxide layer on their surface. A preferred multiphase particle is alumina or silica coated with layer with a similar composition as the underlying dielectric layer such as silica, low K dielectric layers, doped silica, carbon doped silica, nano-porous silica or a low K dielectric layer. More preferred multiphase particles include alumina coated with silica, silica coated with nano-porous silica, and silica coated with cerium oxide. The thickness of the coatings can vary from 0.5 nm to 500 nm.

The preferred thickness of the solid non-soluble coating on the core particle is between 10 nm to 100 nm. The solid coating can be zirconia, alumina, titania, silicon nitride, silicon carbide, insoluble polymeric materials and its mixture, its composition being different from its internal (core) composition. The coatings can be continuous or discrete and provide 10 to 100% core particle surface area coverage. The coatings preferably have different/polymer adsorption characteristics compared to the bulk material comprising the particle.

Nanoporous particles, such as shown in FIG. 4(d) may be particles which provide nanosized pores having sizes varying from size ranging from 5 nm to 50 microns and pore size ranging from 1 Å to 100 Å. The porosity of the nano-porous particles can range from 0.1% to 80%.

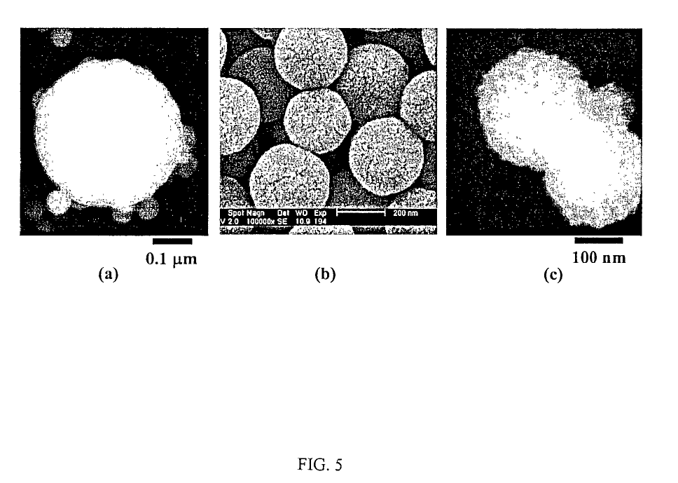

FIGS. 5(a)-(c) show examples of coated particles. FIG. 5(a) shows alumina coated with silica. FIG. 5(b) shows silica coated with nanoporous silica. FIG. 5(c) shows silica coated with cerium oxide. All three coatings were formed by wet precipitation techniques. The coating thickness varied from 0.5 nm to 50 nm. By applying a solid coating to form multiphase core particles, both bulk mechanical properties and the surface adsorption properties of the particles can be tailored.

A preferred example of a two phase composite particle is silica and silicon nitride. A preferred example of a nano-porous particle is nanoporous silica with porosity varying from 1% to 80% of the total volume.

Nano-porous silica particles can be formed by a modified Stober process (W. Stober, A. Fink, E. Bohn, J. Colloids and Interfacial Science, 26, 62-69 (1968)). The particle size can vary from 200 nm to 500 nm, while the porosity can vary from 10 to 60%. As the porosity of the surface increase the number of adsorption sites are expected to decrease.

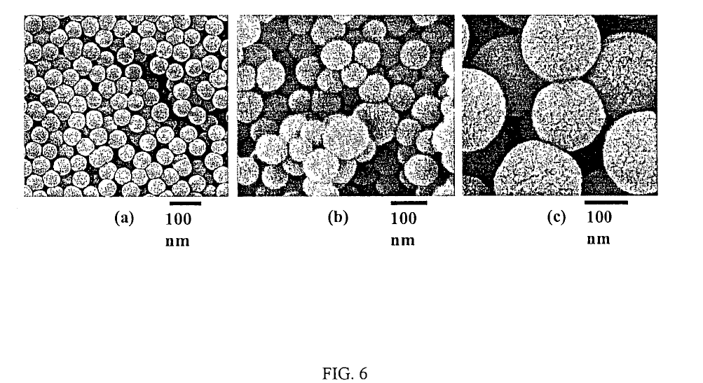

FIGS. 6(a)-(c) show TEM photographs of various core particles showing different nanoporous core particle sizes. The particles are mono-dispersed and spherical in nature. FIG. 6(a) shows 50 nm particles having 24% porosity, while FIG. 6(b) shows 100 nm particles having 30% porosity. FIG. 6(c) shows 200 nm particles having 38% porosity. It is noted that the aspect ratio of particles can be changed using alternate formation methods.

The adsorption additive in the continuous abrasive slurry based on selective substantial adsorption onto the dielectric is selected so that the layer(s) to be polished, such as a metal film, does not substantially adsorb the selective adsorption additive, while the selective adsorption additive adsorbs strongly on the underlying dielectric layer, such as SiO₂ or a low K dielectric layer. This leads to significant polishing of the metal film, but no significant polishing of the underlying dielectric layer.

The adsorption additive can be one or more surfactants or polymers. The selective adsorption additive can be a surfactant which shows specific selective adsorption characteristics with inorganic particle cores, dielectric films, metal based films and metal embedded (e.g. copper, silver) films. The surfactant/polymer additive should be not substantially adsorbed by the layers to be polished, such as a gate or interconnect metal layer (e.g. copper or silver) or refractory metal based barrier layers (e.g. Ta).

In another embodiment of the abrasive based continuous slurry, the selective adsorption additive exhibit substantial adsorption on the dielectric below a certain predetermined pressure. This leads to pressure dependent polishing characteristics. The predetermined pressure can be from 0 to 5 psi, 1 to 10 psi, or 2 to 18 psi. At sufficiently high pressure, the selective adsorption additive is removed from the dielectric surface leading to a high dielectric polishing rate. At lower pressure, due to substantial adsorption of the surfactant, the polishing rate is very low. Thus the “high regions” on the dielectric surface are polished, whereas the low pressure “low regions” do not polish, resulting in higher planarity of the surface. This leads to tunable selectivity and resulting high planarity polishing of the dielectric surface . Once the dielectric surface is planarized, the polishing rate is substantially reduced. Preferred additives to achieve these characteristics comprise a mixture of two surfactants with one surfactant from at least two of the groups consisting of anionic, cationic, zwitterionic and non-ionic surfactants.

A variety of surfactants or polymer additives can be used with the invention. Surfactants are generally characterized by a hydrophilic head group and a hydrophobic tail group. Examples of hydrophobic tail groups include straight chain, long alkyl groups (carbon chain length generally varying from C₈ to C₂₀), branched chains, long chain (C₈-C₁₅) alklybenzene residues, long chain periluoroalkyl groups, polysiloxane groups and high molecular weight propylene oxide polymers.

Surfactants can either be cationic, anionic, zwitterionic or non-ionic. The surfactants can be used individually or in a mixed state. “Critical Micelle Concentrations of Aqueous Surfactant Systems” by P. Mukherjee and K. Mysels, published by National Data Standards Reference Service—National Bureaus of Standards (presently call NIST)—NSRDS-NBS-36 (1971) pgs. 23-50 (“Mukherjee”) and “Surfactants and Interfacial Phenomena” by M. J. Rosen, John Wiley & Sons, 1989, (“Rosen”), on pages 3-32, 52-54, 70-80, 122-132, and 398-401 provide numerous examples of surfactants. Mukherjee also lists the bulk CMC values for the various surfactants. The bulk CMC value of a surfactant is defined as the minimum concentration at which the surfactant self assembles to form structured layers in a bulk solution.

Mixed adsorption additives can be used with the invention. In certain cases it may be advantageous to use mixed surfactants to control the adsorption density, the strength of the surfactant adsorption. Examples of some possible synergistic effects are described on pg. 398-401 of Rosen. For example, mixtures of surfactants can include, cationic and non-ionic, cationic and zwitterionic, cationic and anionic, cationic and non-ionic and anionic, cationic and zwitterionic and nonionic, and other combinations of surfactants. In each of these surfactants, the head group and the tail group can be varied to provide similar effects in the slurry but at different concentration levels. Additionally, some salts may be added which control the strength of the surfactant adsorption.

The concentration of the surfactant can be from 0.01 times of a bulk CMC of the solution to 1000 times of the CMC. Preferably, the surfactant concentration is from 0.4 of the CMC to 100 times of the CMC. If CMC values not known or not available, the surfactant concentration can be set in a range from 0.1 mM to 500 mM.

Examples of cationic surfactants include long chain amines and their salts, diamines and polyamines and their salts, quaternary ammonium salts, cetylpyridium bromide, polyoxyethylenated (POE) long chain amines, quaterized polyoxyethylenated long chain amines, amine oxides and cetyl trimethyl ammonium (CTAB) and cetyl trimethyl ammonium chloride (CTAC). Preferred cationic surfactants include dodecyl trimethylammonium bromide (C₁₂TAB) and related compounds, such as C₈TAB, C₁₀TAB, C₁₄TAB, C₁₆TAB, C₁₈TAB, with varying hydrophobic chain lengths and cetyl trimethyl ammonium chloride (CTAC). Other preferred examples of cationic surfactants include dodecylammonium chloride, cetylpyridium bromide. In each of these cases, the hydrophobic chain length is preferably varied from C₈ to C₂₀. Examples of preferred cationic based surfactants for structures including silicon dioxide include CTAB, and CTAC, and their derivatives and chemical equivalents.

Examples of anionic surfactants include carboxylic acid salts, amine salts, acylated polypetides, sulfonic salts, higher alkylbenzene sulfonates, secondary n-alkanesulfonates, triethanolamine lauryl sulfate, ammonium lauryl sulfate, sodium alkene sulfate (SAS), sodium dodecyl sulfate (SDS), olefin sulfonates (AOS), sulfosuccinate esters, sulfated linear primary alcohols, sulfuric acid ester salts, Hamposyl class of surfactants (manufactured by Dow Chemicals), the Zonyl Class of surfactants (manufactured by the Dupont Company), phosphoric amides, polyphosporic acid esters and perfluorinated anionics. Preferred anionic surfactants include SDS and SAS and their alkali free derivatives, triethanolamine lauryl sulfate, ammonium lauryl sulfate, Hamposyl and Zonyl. For alumina-like surfaces, such as alumina particles or particles coated with an alumina layer, the preferred surfactants are either anionic and zwitterionic. Examples of preferred anionic surfactants for alumina like surfaces include sodium dodecyl sulfate (SDS), triethanolamine lauryl sulfate and ammonium lauryl sulfate.

Examples of zwitterionics include B-N alkylaminopropionic acids, N alkyl-B iminodipropionic acids, imidazoline carboxylates, N-alkylbetanies, amine oxides, sulfobetaines and KETJENLUBE 522®. KETJENLUBE 522® is the current tradename for what had been called DAPRAL GE 202®, now produced by the Akzo Nobel Functional Chemicals Company, Netherlands. This material is a water soluble copolymer of an average molecular weight of approximately 15,000 consisting of a-olefins and dicarboxylic acids, partially esterified with an ethoxilated alcohol. KENJENLUBE 522® is highly lubricating and dispersing and is a preferred zwitterionic surfactant for polishing structures including silicon dioxide or for alumina-like surfaces, such as alumina particles or particles coated with an alumina layer.

Examples of non-ionic surfactants include polyoxyethlyenated alkylphenols, alkylphenol, polyoxyethlyenated straight chain alcohols, polyoxyethlyenated polyoxypropylene glycols, polyoxyethlyenated mercaptans, long chain carboxylic acid esters polyoxyethlyenated silicones, tertiary acetylenic glycols and TRITON X-100® manufactured by the Dow Chemical Corporation, MI. TRITON X-100® is octylphenol ethylene oxide condensate and is also referred to as Octoxynol-9. This material has a molecular weight of 625 Daltons. Preferred non-ionic surfactants include Tween 80®, Triton X. TWEEN-80® is manufactured by the ICI group of Companies, New Castle, Del. TWEEN 80® is polyoxyethylene sorbitan monooleate, and has the following synonyms: polyoxyethylene sorbitol ester; polysorbate 80 and PEG (20) sorbitan monooleate. This material has the molecular formula C₆₄H₁₂₄O₂₆₃ and a corresponding molecular weight of 13103 Daltons. Preferred examples of non-ionic surfactants include TWEEN-80® and the family of TRITON X® compounds. TWEEN-80™ is manufactured by the ICI group of Companies, New Castle, Del.

The concentration of the surface-active selective adsorption additives is generally provided such that they are strongly adsorbed to the surface of the particle cores and the underlying dielectric. The concentration in which the micelles form in the bulk of the materials (CMC) varies with the hydrophobic tail and hydrophilic head groups of the surfactant, and presence of the other additives in the solution. The strength of the surfactant adsorption on the surface of the particle or the dielectric surface depends on the density and the nature of adsorption sites on the surface and the chemistry of the solutions.

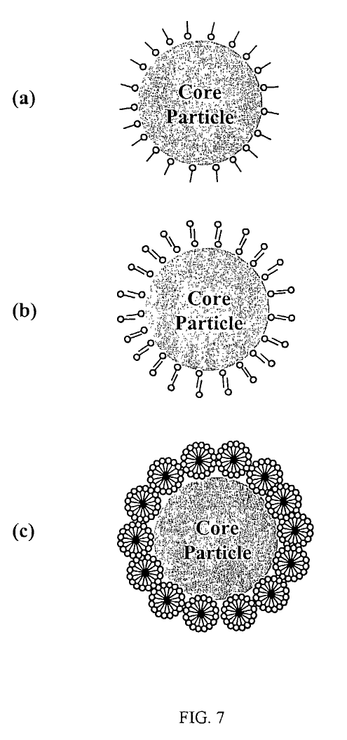

FIGS. 7(a)-(c) show some possible configurations of composite particles suitable for use in a slurry, the composite particles having various surfactant layer structures disposed on core particles. In each configuration shown, the core (e.g. silica) particles are surrounded by a surfactant shell. For example, the core particles can be selected from the composite particles shown in FIGS. 4(a)-(d).

The surfactants or polymers can provide selective adsorption characteristics on different surfaces exposed to the slurry or reductions in selectivity, such as when used in an interval slurry in the case of selective adsorption. For example, the surfactant or polymer preferably can provide strong adsorption to the slurry particles (if present) and underlying insulating dielectric layers, such as silicon dioxide. The formation of a selective highly adsorbed layer on the slurry particles and the dielectric surface leads to several helpful properties.

Slurry stability can be improved by the surfactant because the surfactant or polymer coated particles tend to repel one another. As a result, they tend not to agglomerate. This repulsion is due to steric force. As a result, the dielectric layer remains substantially unchanged by the metal polishing process because there is essentially no particle-surface contact at the dielectric surface. Accordingly, there is little or no scratching or peeling of the dielectric layer. The dielectric surface may also be cleaned during metal layer polishing due to repulsion of particles from dielectric surface. Thus, the formation of the composite particles having a hard core and soft additive shell along with strongly adsorbed surfactant layers on insulating surfaces results in improved CMP metal polishing results.

A preferred embodiment of the invention for abrasive based continuous slurries including selective substantial adsorption on the dielectric uses silica or silica inorganic cores coated with surfactants to form a hard core-soft shell structure. The inorganic cores can be silica, doped silica, porous silica, or hard particles. For silica/nanoporous or silica/nanoporous silica coated inorganic cores, the preferred surfactant is cationic, zwitterionic, or a mixture of cationic/non-ionic surfactants.

The selective adsorption additive may include one or more soluble polymers which are adsorbed onto the surface of the dielectric film and the particles in the slurry, if present. Polymers can be selected from polyethylene oxide (PEO), polyacrylic acid (PAA), polyacryamide (PAM), polyvinylalcohol (PVA) and polyalkyamine (PAH). Alternatively, the surfactant additives described above can be supplanted or used in combination with these polymeric additives and related polymeric compounds. These polymer additives can also be used as dispersants for particles in the slurry. The concentration of the polymer additives preferably varies from 1 mg/liter to 10 g/liter of solution. A preferred concentration of the polymeric additives varies from 10 mg/liter to 1 gm/liter. The molecular weight of the polymeric additive can vary from about 100 to about 1,000,000 Daltons. The preferred molecular weight of the additive varies between about 1,000 to 10,000 Daltons.

Polymeric additives are generally chosen based on the nature of the surface sites for polymeric adsorption. For example, if silica surface based slurry particle cores are used, the preferred choice of additives is PEO or PVA. If silicon nitride slurry particle cores are used, the preferred polymer additive is PAA, which generally strongly adsorbs to the silicon nitride cores. For the metal layers such as copper, tantalum and silver, several mercaptans, and thiol based compounds can be readily adsorbed to theses surfaces and can be readily used to modulate the polishing characteristics.

Additionally, some salts may be added to control the strength of the surfactant adsorption. In some of these examples, the hydrophilic head groups contain alkali metals such as Na and K. However, it may be possible to replace the alkali metals with other cations (such as ammonium based) which may be more compatible with semiconductor processing.

The adsorption of surfactant and its self assembly can be measured by a combination of several techniques, including Fourier transform infrared spectroscopy (FTIR), adsorption density measurement via the solution, the depletion method, contact angle measurements and surface force measurements via atomic force microscopy (AFM). The confirmation of micelles at the surface and the bulk of the solution can be investigated using FTIR, AFM, and electrical conductivity and surface tension/contact angle measurements.

To quantify the selective adsorption characteristics of surfactants or polymers additives, this application will define certain new terminology in relation to new measurement techniques. Standard measurement techniques and measures of adsorption density of surfactants use solution depletion methods, contact angle, zeta potential or atomic force microscopy (AFM). These conventional methods have been found to be inadequate to describe the effects of adsorption phenomena on resulting CMP characteristics. Some of the shortcomings of conventional measurement methods include the inability to conduct measurements during actual CMP conditions where interactive effects may play a critical role. Moreover, conventional methods are known to produce results which generally lack correlation with the CMP polishing rate. As described below, new variables have been defined herein, such as adsorption ratios (AR) and selective adsorption ratios (SAR) to correspond to parameters measured when using slurries according to the invention together with the new measurement parameters and techniques.

The adsorption and the selective adsorption characteristics of surfactants and polymer additives on various surfaces when immersed in a slurry can be defined by the adsorption ratio (AR) and selective adsorption ratio (SAR), respectively. The adsorption ratio of a material X is denoted as AR_{X} and is defined as the CMP polish rate without the surfactant or polymer additive divided by the CMP polish rate in presence of the surfactant or polymer additive. The AR is generally always greater than or equal to 1, since the polishing rate of a given material can only generally decrease upon the addition of a surfactant or a polymer additive which exhibits surfactant-like properties. However, in cases where the surfactant destabilizes slurry, AR values can be less than 1.0.

ARX(C)=(CMP Polish Rate without surfactant)/(CMP Polish Rate with surfactant).

Where C corresponds to the concentration of the surfactant or polymer additive. The AR parameter also permits an objective definition of what constitutes substantial adsorption of an additive in relation to one or more layers. As noted earlier, “substantial adsorption” relative to a given layer refers to a CMP polishing rate (for a given slurry and CMP polishing conditions) without the selective adsorption additive being at least three (3) times the CMP polishing rate with the selective adsorption additive, while non-substantial adsorption relative to a given film refers to a CMP polishing rate (for a given slurry and CMP polishing conditions) without the selective adsorption additive being less than or equal to three (3) times the polishing rate of the layer with the selective adsorption additive.

In the case of strong adsorption of the selective adsorption additive, such as by a dielectric layer, AR values can be at least 50, preferably greater than 100, and even 1,000 or more in certain embodiments. This condition can occur when the adsorption additive provides substantial adsorption to both the dielectric and the inorganic core particles.

Preferably, surfactants or polymer additives are added to the slurry such that the AR values of the underlying dielectric is kept large, typically greater 50, while the AR values of the metal is typically kept generally below about 3.0.

Selective adsorption ratios (SARs) compare the adsorption ratios of two materials, such as X and Y. The adsorption selectivity of material X compared to material Y, denoted by SAR_{X/Y} at a particular concentration “C” of the surfactant or polymer additive is defined as the value of AR_{X} divided by the value of AR_{Y}:

SAR_{X/Y}(C)=AR_{X}(C)/AR_{Y}(C)

Both AR_{X}(C) and SAR_{X/Y}(C) are generally a function of the type and the concentration (C) of the surfactant or polymeric selective adsorption additive. The higher the SAR, the higher the selectivity of additive adsorption. If Y is a metal, such as Ta, Cu, W, Pt or Ag, or alloys thereof, while X is a dielectric such as silicon dioxide or a low K dielectric, to achieve high SAR_{Dielectric/metal} values it is necessary to have high values of AR_{Dielectric} and low values of ARₘₑₜₐₗ. Thus, the selective adsorption additive is preferably selectively adsorbed by the dielectric to achieve high SAR_{Dielectric/metal} values. In experiments performed, SAR_{Dielectric/metal} were found to vary from 1.0 to over 4,000.

The selectivity of CMP polishing of material X divided by the CMP polish rate of material Y at a concentration “C” of the surfactant or polymer additive is denoted herein as S_{X/Y}(C), and can be expressed by the following equation:

S_{X/Y}(C)=SAR_{Y/X}(C)×S_{X/Y}(0)

Where S_{X/Y}(0) is the ratio of the CMP polish rates of material X and Y when no polymeric or surfactant selective adsorption additives are added to the slurry. It is noted that SAR_{Y/X}(C)=1/SAR_{X/Y}(C). This equation shows that to achieve high selectivity the additive should generally be chosen so that the SAR values and the selectivity at zero concentration should be maximized. The equation metal/dielectric selectivity can be represented as shown below:

S_{metal/Dielectric}(C)=SAR_{Dielectric/metal}(C)×S_{metal/Dielectric}(0)

To achieve high metal to dielectric selectivity (S_{metal/Dielectric}) value, the selective adsorption ratios of the metal to dielectric (SAR_{dielectric/metal}) should be maximized.

During CMP polishing, the weakly adhered selective adsorption additive layer on the metal are generally removed by the applied pad pressure, while the strongly adsorbed layers on the slurry particles (if present) and the dielectric layer are generally not removed. This results in a high polishing rate for the metal and a low polishing rate for the dielectric. In an alternate embodiment of the invention, by using a pressure dependent selective additive adsorption, both high selectivity and high planarity of the dielectric layer can be achieved after polishing.

The continuous abrasive based slurry including selective dielectric adsorption additives can include at least one oxidizer. For example, peroxides, iodates, bromates, chlorates, permanganates, ferricyanides, nitrous acid, hypochlorites, hypobromidies, hypoiodides, perchlorates, perbromates and periodic acid may be used.

In another embodiment of the abrasive based continuous slurry, the slurry may contain at least one additive which forms a soft layer on the surface of the metal layer. The soft layer can be easily removed by abrasive particles, thus resulting in high removal rates. Additives that form soft layers includes halogens, halides, such as those including iodine and bromine, interhalogen and mixed compounds such as ICl, IBr, ICl₃, IBr₃, HBr, HI, HBrO, HIO, BrCl, and other compounds such as HNO₂, sulfites, polysufides, thiosulfates, thionic acids and peroxydisulfates. Other examples of soft layers include complexes of halides with surfactants, salts, complexing agents and corrosion inhibitors. A preferred soft layer includes copper-azoles-halide complexes. Preferred examples of metal layers include conducting metals such as copper, silver and gold, refractory metals such tungsten, tantalum, platinum, and their alloys. To reduce scratching and other effects, the particles preferably are un-agglomerated having sizes less than 500 nm, and even more preferably having sizes less than 100 nm. A preferred particle is silica with a size range from 5 nm to 500 nm. The abrasive based continuous slurry including adsorption additives may also contain either anionic, cationic, non-ionic or zwitterionic surfactants or polymer additives as discussed earlier.

Another embodiment of the continuous slurry is the use is the “abrasive-free” slurry. In the case of abrasive-free continuous slurries, high selectivity can be achieved by using chemicals which rapidly form a soft film on the surface of the metal. The soft layer can be removed by either the pad or with soft particles, or abrasive core particles coated with soft layers, or by silicon dioxide particles with average particle sizes less than 150 nm.

Additives that form soft layers include iodine, bromine, halides. Preferred examples of metal layers include highly conducting metals such as copper, silver and gold. Preferably, the soft layer is a non oxide layer such as a halide such as a iodide, bromide, chloride, sulfide, hydroxide and the mixture of these materials with oxide, nitride and complexation compounds. The soft layer formation additive preferably does not interact strongly with the underlying refractory metal or the dielectric layer, thus resulting in low removal rates and high selectivity of the polishing process.

The continuous slurry including abrasive-free or abrasive based slurries can include optional additives other than particles. These other additives may include corrosion inhibitors, solubilizing agents, complexation agents, etching agents, pH stabilizers, oxide film forming oxidizers, particle dispersants and stabilizers, surface uniformity agents, other reaction additives and salts.

The continuous slurry whether abrasive or abrasive-free can include passivation additives. The passivating additives can include azoles, such as benzotriazole (BTA), tolytriazole (TTA), imidazole, pyrazole caboxybenzotriazole, 1-phenyl-5-mercaptotetrazole, thiols, oxalic acid, amines such as p-toluidine, salicycladoxime, benzoionoxime, tetramines such as hexatetramine, mercaptans, benzoates, sodium hexanoates, and carboxylic acid, ethanolamine, cinnamates and hydroxyquinoline. The concentration of the passivating additive is preferably from about 1 μM to 500 mM. The preferred passivating additives are azoles, BTA, TTA, imidazole and mercaptans.

The pH of the continuous slurry including abrasive and abrasive-free formulations can be from 1.5 to 13. Preferably, the pH of the continuous slurry is from 2 to 10.

The continuous slurry may include a complexing agent. The complexing agent can be acetic acid, citric acid, tartaric acid or succinic acid, glycine, amino acides and their mixtures. Other examples include nitric acid, acetic acid, sulfuric acid, hydroxy acid, carboxylic acid, citric acid, malic acid, malonic acid, succinic acid, phtalic acid, tartaric acid, dihydroxysuccinic acid, lactic acid, malic acid, fumaric acid, adipic acid, maleic acid, glutaric acid, oxalic acid, benzoic acid, propionic acid, butyric acid and valeric acid, and other organic acids, EDTA, and hydroxyquinoline.

The continuous slurry can also include at least one salt. The salt can be selected from chlorides, bromides, iodides, nitrates, pthalates, or soluble potassium, sodium, ammonium based salts, and their mixtures. The concentration of salt can be 0.1 mM to 0.5 M. A preferred concentration of salt is from 1 mM to 50 mM.

The continuous slurry can contain halide solubilizing agents, since halides are generally sparingly soluble in water. Examples include, esters, alcohols, glycerols, carbon tetrachloride, chloroform and other non-polar solvents as well as soluble potassium, ammonium, sodium salts, bromides, chlorides, and iodides.

The continuous abrasive and abrasive-free slurry can provide a selectivity of at least approximately 40, preferably at least 100, more preferably at least 500, and most preferably at least 1,000 for the metal film compared to a dielectric film, such as silicon dioxide, low K film, alumina or silicon nitride. The term selectivity refers to the CMP polishing rate of the metal film when compared to the dielectric film polishing rate.

The continuous abrasive and abrasive-free slurry can provide a selectivity of at least approximately 40, preferably at least 100 for the metal film compared to a refractory metal underlayer.

The continuous abrasive slurry based on selective additive adsorption can provide an adsorption ratio (AR) for a metal comprising film of no more than 3.0, and the dielectric film of at least 10. The AR of the dielectric film is preferably at least 50, more preferably at least 250, and most preferably at least 1000. The continuous abrasive based slurry can provide a selective adsorption ratio (SAR) of the dielectric film to the metal based film of at least 10 to 50, preferably at least 100, and more preferably at least 500.

The invention also provides a method to achieve tunable selectivity, the tunable aspect preferably used near the end of the polishing process. Generally, the high selectivity continuous slurry, whether abrasive or abrasive-free, is applied throughout the polishing process. If high selectivity is achieved by the continuous slurry, the polishing process is expected to virtually stop at the underlying substrate upon being reached. Thus, the polishing process can provide a large polishing window and uniformity of polish when using the high selectivity process. However, it is likely that the high selectivity may lead to enhanced “dishing” which is characterized by a formation a dish like structure in the embedded metallic layer, which has a faster polishing rate relative to the underlying substrate. This results in an enhanced surface topography at the end of the polishing process. To reduce dishing, the invention provides an interval slurry for specific time interval which together with the continuous slurry can significantly reduce surface topography by increasing the removal of the dielectric for one or more specified periods of time. The surface topography can also be reduced by decreasing the polishing rate of the metal layer. In both of these cases, the selectivity of the metal/dielectric and metal/refractory metal process can be decreased by the addition of the interval slurry.

For example, when the continuous abrasive based slurry and the interval slurry are mixed, the adsorption strength of the adsorption additive on the dielectric, and/or the slurry particles generally decrease. Because of the destabilization of the adsorption additive, the polishing rate of the dielectric will generally increase. With further dilution of the abrasive concentration, the dielectric removal rate will reach a maximum value followed by a reduction in rate. Simultaneously, the metal removal rate may also decrease due to dilution effects of the abrasive, corrosion inhibitors, the oxidizing agents or soft film forming agents. These factors can lead to a substantial reduction in the selectivity of the polishing process. Thus, the additional of the interval slurry to the continuous abrasive based slurry to form a mixed slurry generally leads to significantly reduced selectivity. The amount of selectivity decrease depends on parameters including the composition of the interval slurry, composition of the continuous slurry and the ratio of the mixing components.

Some possible methods for destabilization the selected adsorption additive is by use of an interval slurry comprising (i) addition of deionized water, (ii) addition of one or more components which of lower concentration of same selective adsorption additive (iii) addition of salts, and (iv) addition of other surfactants and additives which destabilize the adsorption of the selective adsorption additive, (v) addition of a dilutant at different pH, and (vi) addition of particles. Each of these methods can be used individually or combined. A preferred method for destabilization of the selective adsorption additive of the continuous slurry is by reducing the concentration of the selective adsorption additive or addition of an additive which creates non-substantial adsorption in the dielectric materials. Examples of such additives include (i) de-ionized water at same pH (ii) de-ionized water at different pH (iii) addition of salts (iv) addition of particles. These additives can be used individually or mixed to obtain optimum results. The selectivity decrease through the addition of the interval slurry to the continuous slurry for an abrasive based slurry is preferably at least be a factor of 1.3, preferably being a factor of 5 or greater.

Another embodiment for achieving tunable selectivity when the interval slurry is added to continuous abrasive or abrasive free slurry involves varying the removal rate of the metal layer. The chemical reaction rate can also be varied by varying the concentration of film forming agents, corrosion inhibition agents, complexation agents, or by varying the concentration of particles in the slurry. A preferred embodiment is by decreasing the removal rate of a soft layer formed on the surface of the metal film. In this embodiment, the interval slurry may decrease the concentration of abrasives, film forming agents, complexation or corrosion inhibition agents. This can also lead to a substantial decrease in the selectivity of the system. These additives can be used individually or mixed to obtain optimum results. The selectivity decrease by the addition of the interval slurry to the continuous abrasive based slurry can be at least by a factor of 1.3, and preferably by factor of 5 of greater.

When the flow of the interval slurry is stopped, the polishing characteristics quickly returns to characteristics obtained from CMP using the continuous slurry alone, which again leads to high selectivity. This high selectivity condition also leads to reduced surface scratching. Thus, the combination of the two slurry system can achieve (i) global planarity and reduced dependence on end-pointing by providing a high selective metal to dielectric polish, (ii) high planarity and reduction of the surface topography by controlled addition of the interval slurry, and (iii) minimization of surface scratching.

Another slurry which provides tunable selectivity comprises a continuous abrasive based slurry which provides highly pressure-dependent polishing rate characteristics. At pressures below a predetermined value, substantial adsorption of the additive on the dielectric film takes place resulting in low removal rate of the dielectric and resulting high metal to dielectric polishing selectivity. If the surface of the dielectric is rough, there are local high pressure regions, which leads to higher local removal rates and thus planarization of the film. The predetermined pressure below which substantial adsorption can take place can be in the range of 0 to 5 psi, 1 to 10 psi, or 1-18 psi.

A method for chemical mechanical polishing (CMP) a structure including a metal-based film and a dielectric film includes a multiple slurry process. The continuous slurry, which can be abrasive or abrasive-free based, is applied to the structure. Overburden regions of the metal based film are then removed using a polishing pad or the abrasives in the slurry trapped in the pad. The metal film is generally first removed at a relatively fast rate because of non-substantial adsorption of the selective adsorption additive. When the interval slurry is added to the continuous abrasive based slurry to form a mixed slurry, the selectivity of the polishing process decreases primarily due to an increase in the dielectric polishing rate and some reduction in the metal polishing rate. The selectivity can also be affected by a change in concentration of optional chemicals which may be present in the slurry, such as oxidizers, soft film forming agents, corrosion inhibitors, particles, salts, surfactants and polymer additives.

Tunable selectivity can also be achieved using an abrasive-free based continuous slurry when combined with an interval slurry. In a preferred example, a continuous slurry including either abrasive or abrasive-free slurries includes a film forming agent to make soft layers or non-oxide layers on the surface of the metal. The continuous slurry achieves high selectivity because the removal rate of the soft layer or the non-oxide is much higher compared to the underlying refractory metal or dielectric layer. With the addition of the interval slurry, a mixed slurry results which provides a lower removal rate of the top metal layer because of reduced reaction rate effects. The selectivity decrease is dependent on the type and concentration of the additives. The mixed slurry can optionally be used, generally during one or more intervals near the end of the metal polishing step. The mixed slurry composition preferably provides a lower metal/refractory metal selectivity as compared to the continuous slurry.

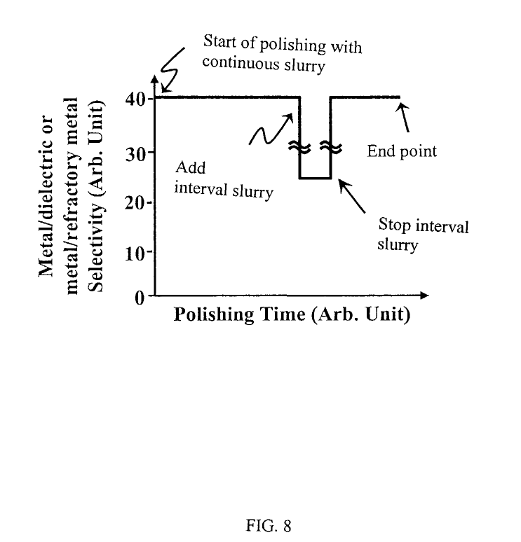

FIG. 8 is a schematic diagram showing time variation in the metal to dielectric selectivity or metal to underlying refractory metal selectivity of a CMP process through the addition of an interval slurry to the continuous abrasive based slurry. Through the first stage of the polishing process, the continuous slurry can be used exclusively. This results in a selectivity of metal/dielectric of 50 or greater. Near the end of the polishing process, the interval slurry is added to the continuous abrasive based slurry as the polishing process proceeds. The interval slurry is preferably introduced after the overburden metal layer becomes partially or nearly cleared from the wafer surface. This event can be detected through detection by a surface sensor using known optical based, friction based or other techniques.

As a result of the addition of the interval slurry, the metal/dielectric selectivity or top metal/ underlying refractory metals can be reduced by factor of 1.3 or more. The interval slurry can be provided for short periods of time, typically 2 minutes or less. As shown in FIG. 8, once the flow of the interval slurry is stopped, the polishing characteristics revert to the high selectivity regime which is a characteristic of the CMP using continuous abrasive based slurry.

This high selectivity condition generally leads to reduced surface scratching. Thus, the combination of the two slurry system can achieve (i) global planarity and reduced dependence on end-pointing by having a high selective metal to dielectric polish, (ii) high planarity and a reduction of the surface topography by controlled addition of the second slurry, and (iii) minimization of surface scratching effects. This process can be used to polish a variety of metal compositions, their alloys, nitrides, carbide, silicides, or their mixtures thereof.

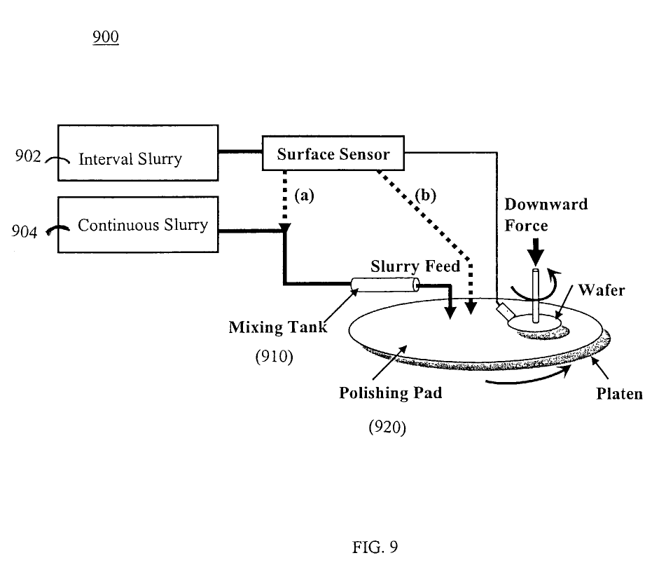

FIG. 9 shows an apparatus 900 designed to feed the interval and continuous slurry for metal polishing. Mixing of the interval slurry 902 and continuous slurry 904 can take place in a mixing tank 910 before being supplied to the CMP tool. Alternatively, the continuous and interval slurries can be mixed on the polishing tool at the point of use (on polishing pad 920). An optical or a frictional based sensor (not shown) can be used to monitor the surface condition of the wafer. Other types of sensing mechanisms based on acoustic, vibration and other techniques can also be used. The interval slurry is typically added when the metal overlayer has been substantially removed from the surface. The apparatus can be used to polish a wide variety of electrically conducting materials including, refractory materials and noble metals, as well as related electrically conducting compounds and mixtures.

### EXAMPLES

A series of experiments were performed to evaluate the CMP performance using a variety of slurry combinations comprising various continuous and interval slurries for polishing various dielectric and metal layers. The CMP experiments were performed using a Rotopol 30 system manufactured by the Struers Company (Cleveland, Ohio). The term RR corresponds to removal rate.

### Example 1

### Tantalum CMP

A structure including tantalum and SiO₂ was polished using varying slurry compositions including abrasive particles. A polishing pressure of 6.7 psi was used in this example, unless otherwise noted. The linear velocity for polishing was approximately 250 feet/minute.

The first composition set included a continuous slurry comprising 5 wt. % 500 nm silica particles, 1 CMC C₁₂TAB, at pH of 9.0. The interval slurry used was DI water adjusted to a pH to 9, or a pH of 6. The polishing rate of tantalum was found to be approximately proportional to applied pressure in the system. At a pressure of 2.5 psi, the polishing rate of tantalum was found to be approximately 140 Å/min.

The mixing ratios of the interval slurry to continuous slurry ranged from 100:1, 10:1, 1:1, 1:10, 1:100. Data obtained demonstrated the ability to reduce the Ta/SiO₂ selectivity by water dilution of the continuous slurry. The removal rate and selectivity is shown in table below. The reduced selectivity is primarily due to an increased rate of removal of silicon dioxide with dilution, followed by a reduced metal polishing rate due to dilution of the slurry.

| Mixing Ratio | | RR of Ta | RR of Silicon | Selectivity |
|---|---|---|---|---|
| (continuous vs. interval) | pH | (Å/min) | Dioxide (A/min) | (Ta/SiO₂) |
| Only Continuous | 9 | 344 | 1 | 344 |
| 100:1 | | 320 | 1 | 320 |
| 10:1 | | 289 | 12 | 24 |
| 1:1 | | 49 | 468 | 0.1 |
| 1:10 | | 6 | 8 | 0.8 |
| 1:100 | | 2 | 1 | 2 |
| Only Interval | | 1 | 1 | 1 |
| Continuous Only | 6 | 96 | 1 | 96 |
| 1:10 | | 15 | 1 | 15 |

The effect of different surfactants in reducing the selectivity of the polishing process was also demonstrated. A continuous slurry comprising 10 weight percent silica with a particle size of 35 nm, 20 mM BTA and 10 CMC of Ketjentube 522, and 50 mM of potassium pthalate was prepared. The interval slurry was DI water adjusted to pH 9. The Ta/SiO₂ selectivity was 344 using the continuous slurry only which was reduced to 0.8 when the mixing ratio of changed to 1:10.

The selectivity change can also be accomplished by using different particles. A slurry using 20 mM C₁₂TAB, 2 mM SDS (sodium dodecyl sulfate), 50 mM KCl and 20 mM BTA was prepared and added to 3 weight % silica coated alumina particles. The interval slurry was 1 weight percent silica at a pH 9.0. When 1:10 ratio of the continuous to interval slurry was prepared, the selectivity decreased from 830 to 2.0. In another example, 5 weight percent of nanoporous silica (20 percent porosity) was used with 1 CMC C₁₄TAB and 20 mM BTA at a pH 9.0. The added component was DI water at pH 9.0 In this case, when a 1:10 continuous to interval slurry was applied, the selectivity was reduced from 215 to 0.7.

A structure comprising tantalum on top of a silicon dioxide was polished with a slurry containing 2 weight percent of 100 nm silica coated alumina particles at pH of 3.0. The polishing pressure was 4.0 psi, 30 mM of benzotriazole, 60 mM CTAB (cationic surfactant) and 0.1 wt percent Dapral GE 202 (zwitterionic surfactant) were added to the slurry. The slurry pH was 4.0. The removal rate of tantalum was approximately 55 nm/min while the removal rate of silicon dioxide was also less than 1 nm per minute. When the polishing pressure was increased to 18 psi, the silicon dioxide polishing rate exceeded 12 nm/min, thus showing non-linear pressure dependent polishing characteristics. It should be noted that these surfactants are only representative of the class of surfactants (e.g. anionic, cationic, zwitterionic, or non-ionic) which can be selected to achieve this effect. Some of the various surfactants that can be chosen are listed in Mukherjee.

### Example II

### TiN Refractory Layer CMP

A structure including TiN and SiO₂ was polished using a slurry including silica particles. A polishing pressure of 6.7 psi and linear polishing speed of 250 ft/min was used in this example. The continuous slurry included 10 wt % silica particles (0.6 micron particle size), 1 CMC C₁₂TAB, 20 mM BTA, 0.1M acetic acid at a pH 9. The interval slurry used was DI water. Data obtained demonstrated the ability to reduce the TiN/SiO₂ selectivity by dilution of the continuous slurry.

| | Mixing Ratio | | | |
|---|---|---|---|---|
| Interval | (continuous vs. | RR of TiN | RR of Silica | Selectivity |
| Component | interval) | (Å/min) | (Å/min) | (TiN/SiO₂) |
| DI Water | Continuous only | 1149 | 1 | 1149.0 |
| | 1:10 | 3014 | 56 | 53.8 |

### Example III

### Copper CMP With Particles

A structure including Cu, Ta and SiO₂ was polished using a slurry including silica, silica coated alumina, and nanoporous silica particles. A polishing pressure of 6.7 psi was used with various slurry compositions. In the first set of experiments, 5 weight % hydrogen peroxide was used. The particles, as well as the composition of the interval slurry was varied. The table below shows the details on the composition of each of the continuous slurries. The table shows that by choosing specific composition and particles, the Ta/silicon dioxide selectivity can be reduced from greater than 50 to less than 10. The details of the continuous slurry are provided below:

Continuous Slurry Compositions:

1) 5 wt. % silica (0.5 micron), 5% H₂O₂, 1 CMC C₁₂TAB, 20 mM BTA, 0.1M acetic acid at pH 6

2) 3 wt % silica coated alumina (0.3 micron), 20 mM C₁₂TAB, 5% H₂O₂, 20 mM BTA, 50 mM citric acid at pH 9 and at 6.7 psi

3) 5 wt % nano-porous silica (0.2 micron), 1 CMC C₁₂TAB, 5% H₂O₂, 20 mM BTA, 50 mM citric acid at pH 9 and at 6.7 psi

| | Interval | | Mixing Ratio | | |
|---|---|---|---|---|---|
| | Component | | (Continuous vs. | | Selectivity |
| Slurry | Slurry | pH | Interval) | Slurry # | (Ta/SiO₂) |
| Slurry 1 | DI Water | 6 | Continuous only | | 68 |
| | | | 1:10 | | 0.5 |
| | 200 mM BTA | | Continuous only | | 68 |
| | | | 1:10 | | 0.3 |
| | 0.5 CMC | | Continuous only | | 68 |
| | C₁₂TAB | | 1:10 | | 1.3 |
| | DI Water | 9 | Continuous only | | 240 |
| | | | 1:10 | | |
| Slurry 2 | DI Water | 9 | Continuous only | | 500 |
| | | | 1:10 | | 10 |
| Slurry 3 | DI Water | 9 | Continuous only | | 89 |
| | | | 1:10 | | 1.4 |

In an another experiment, halides such as iodine was used to form a soft surface layer on copper. The experiments were conducted at a polishing pressure of 6.7 psi at pH 6.0 and using DI water as the interval slurry. The continuous slurry contained 5 wt. % abrasives including silica, alumina, silica coated alumina and nanoporous alumina. The concentration of iodine was varied from 1 mN to 200 mN. However, for the example shown below the concentration of iodine was kept at 10 mN. To dissolve iodine in the solution a small amount (less than 1%) of ethanol, sodium chloride, iodide, or butanol was used. To stabilize the particles, a perfluoric anionic surfactant (FSP™ and Zonyl™ manufactured by Dupont Company, Delaware) was used. In all these experiments the surface of copper was covered with a thin soft layer of primarily an iodide phase. The soft surface film was found to be easily removed by the mechanical polishing pad. The table shows the characteristics of the slurry and the mixing ratio of the continuous and interval slurries and the Copper/Tantalum selectivity. The table shows that the copper to tantalum selectivity is greater than 30 in all cases and decreases to less than 5.0 when the 1:10 continuous to interval slurries mixtures are used.

| | | | Mixing Ratio | |
|---|---|---|---|---|
| | Average | | (continuous vs. | Selectivity |
| Abrasives | Particle Size | | interval) | (Cu/Ta) |
| Silica | 35 | nm | Continuous only | 31.0 |
| | | | 1:10 | 3.3 |
| | 600 | nm | Continuous only | 34.0 |
| | | | 1:10 | 1.3 |
| Silica coated alumina | 300 | nm | Continuous only | 31.4 |
| | | | 1:10 | 1.9 |
| Nano-porous silica | 200 | nm | Continuous only | 34.9 |
| | | | 1:10 | 3.0 |

It should be noted that several anionic, cationic, zwitterionic, or non-ionic surfactants and polymer additives can be used in the slurry. Examples of other surfactants that can be added include non-ionic surfactants such as TX-100, Tween 80, Zwitteronic surfactants such as Ketjentube 522, and cationic surfactants such as C₈TAB, C₁₄TAB. Other examples of potentially suitable surfactants are listed in the detailed description or references cited therein.

It should be noted that similar results can be obtained if bromine based compounds are used. However, in this case a bromide layer instead of an iodide layer will be formed. Besides the use of halogens, one can used mixed halogen systems, such as ICl, IBr and HIO to form soft, non-oxide films on the surface of metals such as copper, silver, tantalum and tungsten.

### Example IV

### Tungsten CMP

The chemical mechanical polishing experiments were conducted on tungsten and silicon dioxide and alumina samples. The experiments were conducted at a polishing pressure of 6.7 psi and linear velocity between 200 and 250 ft/minute. Studies were conducted at pH of 4.0. The first set of experiments were conducted using 10 weight % of 35 nm size silica particles with 10 mM iodine solution, 20 mM BTA, and 100 mM of citric acid. A tungsten polishing rate of 100 nm/min was obtained. The tungsten to alumina selectivity was greater than 30 which reduced to 5.5 when the continuous slurry was mixed at a ratio of 1:10 with an interval slurry composed of DI water.

Another set of experiments involved the use of a slurry with 10 weight % silica particles of average size of 35 nm, 5 wt % potassium iodate, 10 CMC C₁₂TAB, and 20 mM BTA at pH of 4.0. A polish rate of 150 nm/min for tungsten was obtained and with a selectivity of 45.6 for W when compared to silicon dioxide. When this continuous slurry was diluted with a 1:10 ratio with an interval slurry comprising deionized water, the W/silicon dioxide polishing selectivity dropped to 1.6.

### Example V

### Abrasive-Free Copper CMP

Copper and silica films were polished with different abrasive-free based slurries as outlined below. The polishing pressure was varied from 2.7 psi to 6.7 psi. The linear velocity during polishing was approximately 250 ft/minute. The following table provides the slurry composition for interval and continuous slurries and the copper to tantalum selectivity achieved. To dissolve the iodine used a small amount (about 1%) of either ethanol, butanol, sodium chloride, or sodium iodide was used. The table shows that the initial copper to tantalum selectivity is typically greater than 500 and can be reduced at least by factor of 3 or more with the addition of the interval slurry. These results were obtained at a polishing pressure of 6.7. If a pressure lower than 2.5 psi was used, the polishing rate of copper was found to decrease in the range of 1.5 to 2.5 from the values obtained at 6.7 psi. As the polishing rate of tantalum was relatively low for abrasive-free slurries, the selectivity of Cu/Ta was still greater than 500 in all cases for polishing pressures of 2.5 psi. When azoles such as BTA or TTA are added to the slurry, instead of a soft copper iodide layer, a soft azole-iodide-copper complex is formed.

1-1 Continuous Slurry: 10 mN iodine at pH 3

Interval Slurry: 1) DI water at pH 3,

1-2 Continuous Slurry: 10 mN iodine at pH 3

Interval Slurry: 5 mM BTA at pH 3

2. Continuous Slurry: 10 mN iodine, 5 mM BTA at pH 3

Interval Slurry: DI water at pH 3

3 Continuous Slurry: 10 mN iodine, 5 mM TTA, 20 mM potassium pthalate at pH 3

Interval Slurry: DI water at pH 3

4. Continuous Slurry: 10 mN iodine, 0.5% Zonyl™ FSP (manufactured by Dupont Chemicals) at pH 3

Interval Slurry: DI water at pH 3

5. Continuous Slurry: 10 mN iodine, 0.5% SDS (sodium dodecyl sulfate) at pH 3

Interval Slurry: DI water at pH 3

6. Continuous Slurry: 10 mN iodine, 5 mM imidazole, 0.5% Zonyl™ FSP, 1 mM glycine, and 0.5% ammonium lauryl sulfate at pH 3

Interval Slurry: DI water at pH 3

7. Continuous Slurry: 10 mN iodine at pH 3

Interval Slurry: DI water at pH 10

8. Continuous Slurry: 10 mN iodine, 1 mM BTA, 2 wt % polystyrene particles, at pH 3

Interval Slurry: DI water at pH 3

| | Mixing Ratio | |
|---|---|---|
| Continuous Slurry | (Continuous vs. Interval) | Selectivity (Cu/Ta) |
| 1-1 | Continuous only | 3142 |
| | 1:10 | 890 |
| 1-2 | Continuous only | 3142 |
| | 1:10 | 34 |
| 2 | Continuous only | 1429 |
| | 1:10 | 758 |
| 3 | Continuous only | 1128 |
| | 1:10 | 599 |
| 4 | Continuous only | 3847 |
| | 1:10 | 753 |
| 5 | Continuous only | 4328 |
| | 1:10 | 510 |
| 6 | Continuous only | 2410 |
| | 1:10 | 316 |
| 7 | Continuous only | 3142 |
| | 1:10 | 162 |
| 8 | Continuous only | 1528 |
| | 1:10 | 430 |

### Example VI

### Other Metals and Dielectrics

Besides use of silicon dioxide and alumina as the dielectric material, a carbon doped silica based low K dielectric was also used in the experiments. The experiments were conducted on tantalum, platinum and low K substrates. The polishing pressure was 6.7 psi while the linear velocity was 250 feet/minute. The composition of the continuous slurry included 10 weight % percent of 35 nm silica particles, 7 CMC C₁₂TAB particles, 20 mM BTA and 0.1 acetic acid at pH 9.0. The interval slurry was DI water. Under these experimental conditions the Ta/silicon dioxide and Pt/silicon dioxide selectivity were found to be 294 and 30.2 respectively. These selectivity values decreased to 0.5 and 0.8 respectively when 1:10 ratio of continuous to interval slurry were used.

While the preferred embodiments of the invention have been illustrated and described, it will be clear that the invention is not so limited. Numerous modifications, changes, variations, substitutions and equivalents will occur to those skilled in the art without departing from the spirit and scope of the present invention as described in the claims.

We claim:

1. A slurry for chemical mechanical polishing (CMP) of a structure including at least one metal based film and at least one underlying dielectric film, comprising:
at least one selective adsorption additive, wherein said selective adsorption additive is substantially adsorbed by said dielectric film but is not substantially adsorbed by said metal based film.

2. The slurry of claim 1, further comprising a plurality of particles.

3. The slurry of claim 2, wherein said plurality of particles comprise composite particles, said composite particles including an abrasive core surrounded by a shell including said selective adsorption additive.

4. The slurry of claim 1, further comprising at least one oxidizer.

5. The slurry of claim 1, wherein said metal based film comprises at least one selected from the group consisting of noble metals, refractory metals, Ni, Fe, and mixtures thereof.

6. The slurry of claim 3, wherein said abrasive cores are multiphase particles, said multiphase particles comprising a first material coated with at least one other material.

7. The slurry of claim 1, wherein said selective adsorption additive comprises at least one surfactant selected from the group consisting of cationic, anionic, non-ionic and zwitterionic surfactants.

8. The slurry of claim 1, wherein a CMP process using said slurry provides a selectivity of at least 30 for said metal based film as compared to said dielectric film.

9. The slurry of claim 1, wherein said dielectric film comprising at least one selected from the group consisting of silicon dioxide, silicon nitride, silicon oxynitride, alumina and low K dielectrics.

10. The slurry of claim 1, wherein said structure includes a refractory metal based barrier film disposed between said metal based film and said dielectric film, said metal film comprising copper or silver, wherein a CMP process using said slurry provides a selectivity of at least approximately 50 for said metal based film as compared to said refractory metal based film or said dielectric film.

11. The slurry of claim 1, wherein said selective adsorption additive is substantially adsorbed by said dielectric film below a certain predetermined pressure, and non-substantially adsorbed above this predetermined pressure.

12. The slurry of claim 11, wherein said predetermined pressure is below 18 psi or 10 psi.

13. The slurry of claim 1, wherein said selective adsorption additive comprises a mixture of surfactants, said surfactant mixture including at least one surfactant from at least two of the groups consisting of anionic, cationic, zwitterionic and non-ionic surfactants.

14. A slurry for chemical mechanical polishing (CMP) a structure including at least one metal based film embedded in a dielectric matrix or on top of a dielectric film, wherein said slurry includes at least one additive which forms a soft layer on a surface of said metal based film.

15. The slurry of claim 14, wherein said metal based film comprises at least one selected from the group consisting of copper, tungsten, silver, tantalum, and alloys and compounds thereof.

16. The slurry of claim 14, wherein said slurry includes either no particles, particles providing a surface hardness of no more than 3.0 on the Mohs scale, or silicon dioxide particles having an average size less than 150 nm.

17. The slurry of claim 14, wherein said slurry includes a plurality of abrasive particles.

18. The slurry of claim 14, wherein said soft layer comprises at least one halide.

19. The slurry of claim 18, wherein said halide is at least one selected from the group consisting of iodides, bromides, chlorides and related compounds, and mixtures thereof.

20. The slurry of claim 14, where said soft layer comprises a halide-azole-metal complex.

21. The slurry of claim 14, wherein said metal is at least one selected from the group consisting of copper, silver, tungsten and aluminum.

22. The slurry of claim 14, wherein a CMP process using said slurry provides a selectivity of at least 50 for said metal based film relative to either said dielectric matrix or dielectric film, or an underlying refractory metal based film.

23. The slurry of claim 14, wherein said dielectric matrix or dielectric film comprises at least one selected from the group consisting of silicon dioxide, silicon nitride, silicon oxynitride, alumina and low K dielectrics.

24. A slurry for chemical mechanical polishing (CMP) a structure including at least one metal based film embedded in a dielectric matrix or on top of a dielectric film, wherein said slurry comprises at least one additive which forms a non-oxide layer on a surface of said metal based film.

25. The slurry of claim 24, wherein said additive comprises a halide.

26. The slurry of claim 25, wherein said halide comprises an iodine containing material.

27. The slurry of claim 19, wherein said non-oxide layer comprises a halide-azole-metal complex.

28. The slurry of claim 19, wherein said non-oxide layer comprises a metal-azole-iodide complex.

29. The slurry of claim 19, wherein said metal based film comprises at least one selected from the group consisting of copper, tungsten, silver, tantalum, and alloys and compounds thereof.

30. The slurry of claim 19, wherein said slurry includes either no particles or particles providing a surface hardness of no more than 3.0 on the Mohs scale, or silicon dioxide particles with an average size of less than 150 nm.

31. The slurry of claim 19, wherein said slurry includes abrasive particles, said abrasive particles having sizes less than 500 nm.

32. The slurry of claim 19, wherein said abrasive particles comprise at least one selected from the group consisting of silicon dioxide, alumina and silicon nitride.

33. The slurry of claim 19, wherein a CMP process using said slurry provides a selectivity of at least 50 for said metal based film relative to said dielectric matrix or said dielectric film.

34. The slurry of claim 33, wherein said metal based film comprises at least one refractory metal.

35. The slurry of claim 19, wherein said dielectric matrix or dielectric film comprises at least one selected from the group consisting of silicon dioxide, silicon nitride, silicon oxynitride, alumina and low K dielectrics.

36. A slurry for chemical mechanical polishing a structure including at least one metal layer embedded in a dielectric matrix or on top of a dielectric film, comprising:
at least one material for forming a soft film on said metal, and
a plurality of particles.

37. The slurry of claim 36, further comprising at least one salt selected from the group consisting of chlorides, bromides, iodides, nitrates, pthalates and soluble potassium, sodium and ammonium based salts.

38. The slurry of claim 36, further comprising at least one corrosion inhibitor or at least one complexing agent.

39. The slurry of claim 36, further comprising at least one surfactant, said surfactant selected from the groups consisting of anionic, non-ionic, cationic and zwitterionic surfactants.

40. The slurry of claim 36, wherein said soft film forming material reacts in said slurry to form halides ions or free halides in said slurry.

41. A slurry for chemical mechanical polishing (CMP) a structure including a metal based film and an underlying dielectric film, comprising:
a first slurry composition providing a first selectivity for removal of said metal based film relative to said dielectric film, said first slurry for use during at least a first time interval, and
a second slurry composition providing a second selectivity for removal of said metal film relative to said dielectric film for use beginning during at least a second time interval, said second time interval being after said first time interval, wherein a selectivity ratio of said first selectivity to said second selectivity is at least 1.3.

42. The slurry of claim 41, wherein said first slurry composition comprises a plurality of abrasive particles.

43. The slurry of claim 41, wherein said first selectivity is at least 50.

44. The slurry of claim 41, wherein said metal film comprises at least one selected from the group consisting of noble metals, refractory metals, Ni, Al, and Fe, and mixtures thereof.

45. The slurry of claim 41, wherein said dielectric film is at least one selected from the group consisting of silicon dioxide, low K dielectrics and alumina.

46. A slurry for chemical mechanical polishing (CMP) a structure including a metal based film, an underlying dielectric film, and a refractory metal based barrier film disposed between said metal film and said dielectric film, comprising:
a first slurry composition providing a first selectivity for removal of said metal based film relative to said refractory metal based barrier film, said first slurry for use during at least a first time interval, and
a second slurry composition providing a second selectivity for removal of said metal based film relative to said refractory metal based barrier film for use beginning during at least a second time interval, said second time interval being after said first time interval, wherein a selectivity ratio of said first selectivity to said second selectivity is at least 1.3.

47. The slurry of claim 46, wherein said first slurry composition includes a plurality of abrasive particles.

48. The slurry of claim 46, wherein said first slurry composition includes either no particles, particles having a hardness of no more than 3.0 on the Mohs scale, or silicon dioxide particles having an average size less than 150 nm.

49. The slurry of claim 46, wherein said first selectivity is at least 50.

50. The slurry of claim 46, wherein said first selectivity is at least 500.

51. The slurry of claim 46, wherein said structure includes a refractory metal based barrier film disposed between said metal film and said dielectric film, wherein a selectivity of said metal film relative to said refractory based metal film provided by said first slurry is at least 50.

52. The slurry of claim 46, wherein said metal film comprises at least one selected from the group consisting of noble metals, refractory metals, Ni, Fe, and mixtures thereof.

53. The slurry of claim 46, wherein said dielectric film is at least one selected from the group consisting of silicon dioxide, silica, low K dielectrics and alumina.

54. A method for chemical mechanical polishing (CMP) a structure including a metal based film and an underlying dielectric film, comprising the steps of:
polishing during at least a first time interval using a first slurry composition, said first slurry providing a first selectivity for removal of said metal based film relative to said dielectric film; and
polishing during a second time interval, said second time interval after said first time interval, using a second slurry composition providing a second selectivity for removal of said metal based film relative to said dielectric film, wherein a selectivity ratio of said first selectivity to said second selectivity is at least 1.3.

55. A method for chemical mechanical polishing (CMP) a structure including a metal based film and an underlying refractory metal based film, comprising the steps of:
polishing during at least a first time interval using a first slurry composition, said first slurry providing a first selectivity for removal of said metal based film relative to said refractory metal based film; and
polishing during a second time interval, said second time interval after said first time interval, using a second slurry composition providing a second selectivity for removal of said metal based film relative to said refractory metal based film, wherein a selectivity ratio of said first selectivity to said second selectivity is at least 1.3.

56. An apparatus for chemical mechanical polishing (CMP) of structures including at least one metal based film and at least one dielectric film, comprising:
structure for applying a first slurry composition during a first time interval, said first slurry providing a first selectivity for removal of said metal based film relative to said dielectric film; and
structure for applying a second slurry composition during a second time interval, said second time interval after said first time interval, said apparatus providing a second selectivity removal of said metal based film relative to said dielectric film, wherein a selectivity ratio of said first selectivity to said second selectivity is at least 1.3.

57. The apparatus of claim 56, wherein said first slurry composition comprises a plurality of abrasive particles, said first selectivity ratio being at least 3.

58. The apparatus of claim 56, wherein said first slurry includes at least one selected from the group consisting of no particles, particles providing a surface hardness of no more than 3.0 on the Mohs scale and silicon dioxide particles having an average size less than 150 nm.

59. The apparatus of claim 56, wherein said second slurry composition includes said first slurry composition and at least one additional slurry additive.

60. The apparatus of claim 56, further comprising structure for mixing said additional slurry additive with said first slurry composition.

61. An apparatus for chemical mechanical polishing (CMP) of structures including at least one metal film and at least one refractory metal film, comprising:
structure for applying a first slurry composition during a first time interval, said first slurry providing a first selectivity for removal of said metal film relative to said refractory metal film; and
structure for applying a second slurry composition during a second time interval, said second time interval after said first time interval, said apparatus providing a second selectivity removal of said metal film relative to said refractory metal film, wherein a selectivity ratio of said first selectivity to said second selectivity is at least 1.3.

62. The apparatus of claim 61, wherein said first slurry composition comprises a plurality of abrasive particles, said selectivity ratio being at least 3.

63. The apparatus of claim 61, wherein said second slurry composition includes said first slurry composition and at least one additional slurry additive.

64. The apparatus of claim 61, wherein said first slurry composition includes at least one selected from the group consisting of no particles, particles providing a surface hardness of no more than 3.0 on the Mohs scale and silicon dioxide particles having an average size less than 150 nm.

65. The apparatus of claim 61, further comprising structure for mixing said second slurry composition with said first slurry composition.
